(19) United States
(12) Patent Application Publication
(10) Pub. No.: US 2026/0247631 A1
(43) Pub. Date: Aug. 20, 2026

(54) CONNECTING ELEMENT FOR PROCESSOR AND MEMORY

(71) Applicant: ADEIA SEMICONDUCTOR TECHNOLOGIES LLC, San Jose, CA (US)

(72) Inventors: Rasit Onur Topaloglu, Poughkeepsie, NY (US); Cyprian Emeka Uzoh, San Jose, CA (US)

(21) Appl. No.: 19/055,386

(22) Filed: Feb. 17, 2025

(51) Int. Cl. H10B 80/00; H01L 23/538; H01L 25/00; H01L 25/065; H01L 25/18

(52) U.S. Cl. CPC H10B 80/00; H10W 70/65; H10W 90/00; H10W 90/22; H10W 90/288; H10W 90/297

(57) ABSTRACT

A structure is disclosed. The structure can include a first processor die, a first memory unit, a first connecting element, and a second connecting element. The first memory unit can be laterally spaced from the first processor die. The first connecting element can be disposed vertically below the first processor die and the first memory unit to electrically connect the first processor die and the first memory unit. The second connecting element can be disposed vertically above the first processor die and the first memory unit to electrically connect the first processor die and the first memory unit. The first processor die can communicate with the first memory unit through at least one of the first connecting element and the second connecting

### BACKGROUND

### Field

This disclosure relates to semiconductor device structures and methods. In particular, some embodiments are directed to methods and structures for connecting semiconductor dies.

### Description of Related Art

The approaches described in this section are approaches that could be pursued, but not necessarily approaches that have been previously conceived or pursued. Therefore, unless otherwise indicated, it should not be assumed that any of the approaches described in this section qualify as prior art merely by virtue of their inclusion in this section.

As sizes of processor chips continue to increase, multiple processor chiplets may be stitched with each other to form a monolithic processor chip. Increasing memory bandwidth of a processor chiplet, reducing memory latency of a processor chiplet, and/or conserving amount of connecting elements used for connecting processor chiplets and memories can be challenging for packaging the monolithic processor chip.

### BRIEF DESCRIPTION OF THE DRAWINGS

These and other features, aspects, and advantages of the disclosure are described with reference to drawings of certain embodiments, which are intended to illustrate, but not to limit, the present disclosure. It is to be understood that the accompanying drawings, which are incorporated in and constitute a part of this specification, are for the purpose of illustrating concepts disclosed herein and may not be to scale.

FIG. 1A illustrates a side schematic sectional view of a bonded structure with high bandwidth memories stacked around a periphery of processor dies.

FIG. 1B illustrates a side schematic sectional view of a bonded structure with high bandwidth memories stacked above processor dies.

FIG. 2A illustrates a side schematic sectional view of an example implementation of a bonded structure with high bandwidth memories stacked around a periphery of processor dies according to some embodiments.

FIG. 2B illustrates a side schematic sectional view of another example implementation of a bonded structure with high bandwidth memories stacked around a periphery of processor dies according to some embodiments.

FIG. 3A illustrates a side schematic sectional view of another example implementation of a bonded structure with high bandwidth memories stacked around a periphery of processor dies according to some embodiments.

FIG. 3B illustrates a side schematic sectional view of another example implementation of a bonded structure with high bandwidth memories stacked around a periphery of processor dies according to some embodiments.

FIG. 4A illustrates a side schematic sectional view of another example implementation of a bonded structure with high bandwidth memories stacked around a periphery of processor dies according to some embodiments.

FIG. 4B illustrates a side schematic sectional view of another example implementation of a bonded structure with high bandwidth memories stacked around a periphery of processor dies according to some embodiments.

FIG. 5 illustrates a side schematic sectional view of another example implementation of a bonded structure with high bandwidth memories stacked around a periphery of processor dies according to some embodiments.

FIGS. 6A and 6B schematically illustrate cross-sectional side views of two elements prior to and after, respectively, a process for forming a directly bonded structure, and more particularly a hybrid bonded structure, according to some embodiments.

### SUMMARY

The systems, methods, and devices described herein each have several aspects, no single one of which is solely responsible for its desirable attributes. Without limiting the scope of this disclosure, several non-limiting features will now be described briefly.

In some aspects, the techniques described herein relate to a structure including: a first processor die; a first memory unit laterally spaced from the first processor die; a first connecting element disposed vertically below the first processor die and the first memory unit, the first connecting element electrically connecting the first processor die and the first memory unit; and a second connecting element disposed vertically above the first processor die and the first memory unit, the second connecting element electrically connecting the first processor die and the first memory unit, wherein the first processor die communicates with the first memory unit through at least one of the first connecting element and the second connecting element.

In some aspects, the techniques described herein relate to a structure, wherein the second connecting element includes a redistribution layer (RDL), and wherein the first processor die communicates with the first memory unit through at least the RDL.

In some aspects, the techniques described herein relate to a structure, wherein the first processor die includes a first through substrate via (TSV), and wherein the first processor die communicates with the first memory unit through the RDL and the first TSV.

In some aspects, the techniques described herein relate to a structure, further including a second processor die laterally spaced from the first processor die such that (i) the first processor die is disposed laterally between the second processor die and the first memory unit and (ii) the RDL is disposed vertically above the second processor die, wherein the second processor die communicates with the first memory unit through at least the RDL.

In some aspects, the techniques described herein relate to a structure, wherein the first processor die includes a neural networking processing unit (NPU), a tensor processing unit (TPU), a system on a chip (SOC), a central processing unit (CPU), or a graphics processing unit (GPU).

In some aspects, the techniques described herein relate to a structure, wherein the first memory unit includes a first stack of memory dies and a first controller logic.

In some aspects, the techniques described herein relate to a structure, wherein the first controller logic is disposed vertically above or below the first stack of memory dies to enable communication between the first stack of memory dies and the first processor die.

In some aspects, the techniques described herein relate to a structure, wherein the first connecting element includes a bridge.

In some aspects, the techniques described herein relate to a structure including: a first processor die; a first dummy device disposed vertically directly above the first processor die; a first memory unit laterally spaced from the first processor die and the first dummy device; a first connecting element disposed vertically below the first processor die and the first memory unit, the first connecting element electrically connecting the first processor die and the first memory unit; and a redistribution layer (RDL) disposed vertically above the first dummy device and the first memory unit for electrically connecting the first processor die and the first memory unit.

In some aspects, the techniques described herein relate to a structure, wherein a combined thickness of the first processor die and the first dummy device equals a thickness of the first memory unit.

In some aspects, the techniques described herein relate to a structure, wherein the first connecting element includes a bridge, and wherein the first processor die communicates with the first memory unit through the bridge.

In some aspects, the techniques described herein relate to a structure, further including a first through substrate via (TSV) routing vertically through the first processor die and the first dummy device, wherein the first processor die communicates with the first memory unit through at least the first TSV and the RDL.

In some aspects, the techniques described herein relate to a structure, wherein the first memory unit includes a first stack of memory dies and a first controller logic that enables communication between the first stack of memory dies and the first processor die.

In some aspects, the techniques described herein relate to a structure, further including a second processor die and a second dummy device laterally spaced from the first processor die and the first dummy device such that (i) the first processor die is disposed laterally between the second processor die and the first memory unit and (ii) the RDL is disposed vertically above the second dummy device and the second processor die, wherein the second processor die communicates with the first memory unit through at least the RDL.

In some aspects, the techniques described herein relate to a structure, further including a second TSV routing vertically through the second processor die and the second dummy device, wherein the second processor die communicates with the first memory unit through at least the second TSV and the RDL.

In some aspects, the techniques described herein relate to a structure, further including a cooling device disposed vertically above the first processor die and the second processor die.

In some aspects, the techniques described herein relate to a structure, further including a first dummy TSV routing vertically through the first processor die and the first dummy device to provide heat dissipation for the first processor die.

In some aspects, the techniques described herein relate to a structure, wherein the first processor die includes a neural networking processing unit (NPU), a tensor processing unit (TPU), a system on a chip (SOC), a central processing unit (CPU), or a graphics processing unit (GPU).

In some aspects, the techniques described herein relate to a structure, wherein the first dummy device includes a passive component.

In some aspects, the techniques described herein relate to a structure, wherein the first dummy device is directly bonded to the first processor die.

In some aspects, the techniques described herein relate to a structure, wherein the RDL is hybrid bonded to the first dummy device and the first memory unit.

In some aspects, the techniques described herein relate to a structure, wherein the first processor die and the first memory unit are disposed vertically above an interposer that includes the first connecting element.

In some aspects, the techniques described herein relate to a structure, further including a second memory unit disposed vertically above the RDL, wherein the first processor die communicates with the second memory unit through at least the RDL and communicates with the first memory unit through the first connecting element.

In some aspects, the techniques described herein relate to a structure including: a first processor die; a second processor die laterally spaced from the first processor die, the first processor die and the second processor die (i) forming at least a portion of a monolithic processor and (ii) disposed around a center of the monolithic processor; a first memory unit laterally spaced from the first processor die and disposed around a first side of the monolithic processor, the first memory unit electrically connected to the first processor die; a second memory unit laterally spaced from the second processor die and disposed around a second side of the monolithic processor, the second memory unit electrically connected to the second processor die; and a redistribution layer (RDL) disposed vertically above the first processor die, the second processor die, the first memory unit, and the second memory unit for at least electrically connecting the first processor die and the second memory unit, and electrically connecting the second processor die and the first memory unit.

In some aspects, the techniques described herein relate to a structure, wherein the first processor die, the second processor die, the first memory unit, and the second memory unit are disposed vertically above an interposer that includes a first bridge and a second bridge.

In some aspects, the techniques described herein relate to a structure, wherein the first memory unit is electrically connected to the first processor die through the first bridge and the second memory unit is electrically connected to the second processor die through the second bridge.

In some aspects, the techniques described herein relate to a structure, wherein the first processor die communicates with the first memory unit through the first bridge, and communicates with the second memory unit through at least the RDL.

In some aspects, the techniques described herein relate to a structure, wherein the second processor die communicates with the second memory unit through the second bridge, and communicates with the first memory unit through at least the RDL.

In some aspects, the techniques described herein relate to a structure, further including a first dummy device disposed vertically directly above the first processor die and a second dummy device disposed vertically directly above the second processor die, wherein the first dummy device and the second dummy device are disposed vertically below the RDL.

In some aspects, the techniques described herein relate to a structure, wherein the first dummy device is hybrid bonded to the first processor die and the second dummy device is hybrid bonded to the second processor die.

In some aspects, the techniques described herein relate to a structure, wherein the RDL is hybrid bonded to the first dummy device, the second dummy device, the first memory unit, and the second memory unit.

In some aspects, the techniques described herein relate to a structure, further including a first through substrate via (TSV) routing vertically through the first processor die and the first dummy device, wherein the first processor die communicates with the second memory unit through at least the first TSV and the RDL.

In some aspects, the techniques described herein relate to a structure, further including a second through substrate via (TSV) routing vertically through the second processor die and the second dummy device, wherein the second processor die communicates with the first memory unit through at least the second TSV and the RDL.

In some aspects, the techniques described herein relate to a structure, further including a third memory unit disposed vertically above the RDL and around the first side of the monolithic processor, wherein the first processor die and the second processor die communicate with the third memory unit through at least the RDL.

In some aspects, the techniques described herein relate to a structure, further including a fourth memory unit disposed vertically above the RDL and around the second side of the monolithic processor, wherein the first processor die and the second processor die communicate with the fourth memory unit through at least the RDL.

In some aspects, the techniques described herein relate to a structure, further including a first plurality of dummy devices disposed vertically directly above the first processor die and a second plurality of dummy devices disposed vertically directly above the second processor die, wherein the first plurality of dummy devices and the second plurality of dummy devices are disposed vertically below the RDL.

In some aspects, the techniques described herein relate to a structure, further including a cooling device disposed vertically directly above the first processor die and the second processor die, and around the center of the monolithic processor.

In some aspects, the techniques described herein relate to a structure, wherein the RDL is hybrid bonded to the first memory unit, the second memory unit, a top dummy device of the first plurality of dummy devices, and a top dummy device of the second plurality of dummy devices.

In some aspects, the techniques described herein relate to a structure, wherein the RDL is directly bonded to the cooling device.

In some aspects, the techniques described herein relate to a structure, wherein the first processor die, the second processor die, the first memory unit, and the second memory unit are encapsulated using organic material or inorganic material.

In some aspects, the techniques described herein relate to a structure, wherein the first processor die, the second processor die, the first memory unit, or the second memory unit is reconstituted.

In some aspects, the techniques described herein relate to a structure, wherein the RDL is hybrid bonded to the first processor die and the first memory unit.

In some aspects, the techniques described herein relate to a structure, wherein the first processor die and the first memory unit are hybrid bonded to the first connecting element.

In some aspects, the techniques described herein relate to a structure, wherein the first processor die and the first memory unit are at least partially embedded in an encapsulant, and wherein the RDL is deposited over the encapsulant, the first processor die, and the first memory unit.

In some aspects, the techniques described herein relate to a method for forming a structure, the method including: bonding a first processor die to a substrate, the substrate including a connecting element and disposed vertically below the first processor die; bonding a first memory unit to the substrate, the substrate disposed vertically below the first memory unit; and forming a redistribution layer (RDL) vertically above at least the first processor die and the first memory unit, wherein the RDL electrically connects at least the first processor die and the first memory unit, and wherein the connecting element electrically connects the first processor die and the first memory unit.

In some aspects, the techniques described herein relate to a method, further including: bonding a second processor die to the substrate, the second processor die laterally spaced from the first processor die and disposed vertically above the substrate, wherein the RDL is formed vertically above the second processor die for electrically connecting the second processor die and the first memory unit.

In some aspects, the techniques described herein relate to a method, further including: bonding a dummy thermal structure to the first processor die and the second processor die, the dummy thermal structure disposed vertically above the first processor die and the second processor die.

In some aspects, the techniques described herein relate to a method, further including: bonding a second memory unit to the RDL, the second memory unit disposed vertically above the RDL, wherein the RDL electrically connects the first processor die and the second memory unit.

In some aspects, the techniques described herein relate to a method, further including: bonding a dummy device to the first processor die, the dummy device disposed vertically above the first processor die, wherein the RDL is formed vertically above the dummy device, and wherein a combined thickness of the first processor die and the dummy device equals a thickness of the first memory unit.

Various combinations of the above and below recited features, embodiments, and aspects are also disclosed and contemplated by the present disclosure.

Additional embodiments of the disclosure are described below in reference to the appended claims, which may serve as an additional summary of the disclosure.

### DETAILED DESCRIPTION

Although several embodiments, examples, and illustrations are disclosed below, it will be understood by those of ordinary skill in the art that the disclosure described herein extends beyond the specifically disclosed embodiments, examples, and illustrations and includes other uses of the disclosure and obvious modifications and equivalents thereof. Embodiments are described with reference to the accompanying figures, wherein like numerals refer to like elements throughout. The terminology used in the description presented herein is not intended to be interpreted in any limited or restrictive manner simply because it is being used in conjunction with a detailed description of some specific embodiments of the disclosure. In addition, embodiments can comprise several novel features. No single feature is solely responsible for its desirable attributes or is essential to practicing the disclosure herein described.

Bridges, interposers, and/or other connecting elements are useful for connecting processor and memory dies in a semiconductor package. However, it can be challenging to implement low latency or high bandwidth connections between processor and memory dies without compromising thermal performance, particularly when areas of processors increase. Some embodiments disclosed herein nevertheless accomplish high bandwidth memory access for processor dies with improved thermal performance by using one or more connecting elements (e.g., redistribution layers (RDLs)) to allow high bandwidth memories (HBMs) disposed around a periphery of a processor chiplet to be accessed both from top and bottom without blocking heat dissipation of the processor chiplet.

There is increasing demand for higher memory bandwidth and higher memory capacity. Providing high speed, high bandwidth connections between memory and processors can be important for some applications. For example, when training an artificial intelligence or machine learning model, performing complex graphical operations, or carrying out other data-intensive tasks, processors (e.g., processor dies) such as central processing units (CPUs), graphical processing units (GPUs), a neural networking processing unit (NPU) die, a tensor processing unit (TPU) die, field programmable gate arrays (FPGAs), application specific integrated circuits (ASICs), and so forth can spend a significant amount of time idle while waiting for data, which can negatively impact performance and increase the time it takes to complete computing tasks.

In conventional semiconductor packages, high bandwidth memories (HBMs) implemented using stacked memory units or dies may be positioned adjacent and connected to a processor (e.g., a GPU or a CPU) through a bridge. For example, memory dies (e.g., DRAM dies) can be positioned laterally to a periphery of a GPU and connected to the GPU through a bridge (e.g., a bridge disposed vertically below the GPU and the memory dies) that includes high density connecting traces and/or vias. However, achieving high bandwidth or high data rate memory access may become more challenging as demands on computing power continue to increase. For example, as sizes of processor chips continue to increase toward or beyond reticle sizes, multiple processor chiplets may be stitched or connected together using massive interposers or bridges to form a large monolithic processor chip. For an individual processor chiplet, latency associated with memories located farther away (e.g., memories that are separated from a processor chiplet by another processor chiplet) from the processor chiplet can be higher (e.g., compared with latency associated with memories located closer to the processor chiplet) at least due to longer wire lengths, the presence of the other processor chiplets and the presence of additional bridges used for connecting processor chiplets and HBMs. This may prevent the processor chiplets from effectively accessing certain HBMs, thereby making access of certain HBMs impractical and/or compromising data transfer efficiency (e.g., reducing memory bandwidth). Further, a processor chiplet may only access memories (e.g., a memory stack) located adjacent or closer to the processor chiplet from the bottom of the memories through the bridge that electrically connects the processor chiplet and the memories. As such, latency between the processor chiplet and a memory die on top of the memory stack may be longer than latency between the processor chiplet and another memory die at the bottom of the memory stack, resulting in less efficient memory access associated with certain memory dies.

To decrease memory latency (e.g., latency between a processor chiplet and memories located farther away), a connecting element such as a bridge interposer can be disposed between a plurality of processor chiplets and one or more memory units that are stacked on or vertically above the bridge interposer and the plurality of processor chiplets. However, each of the one or more memory units may also only be accessed by the plurality of processor chiplets from the bottom, leading to longer memory latency associated with memory dies disposed toward the top of a memory stack. Additionally, disposing memory units directly above processor dies can impede effective heat dissipation. For example, heat generated by a processor chiplet may need to pass through memory units disposed above, which can lead to the heat been trapped or blocked from dissipation. As such, it can be difficult for a bonded structure utilizing the bridge interposer to manage and dissipate heat efficiently, potentially affecting the performance and reliability of the bonded structure.

To address at least a portion of the aforementioned problems, some embodiments herein utilize one or more connecting elements (e.g., a redistribution layer (RDL), through-substrate-vias (TSVs), and/or the like) to enable high bandwidth and/or high data rate communications between processor chiplets and memory units that are disposed around peripheries of the processor chiplets. In some embodiments, a RDL (e.g., a top-side RDL) may be disposed vertically above processor chiplet(s) (e.g., GPU, CPU, TPU, NPU, or the like) and memory unit(s) (e.g., a plurality of DRAM dies and optional logics) to allow a processor chiplet to access a memory unit both from top and bottom sides of the memory unit. Advantageously, accessing a memory unit both from top (e.g., through the RDL) and bottom (e.g., through a bridge) can double memory bandwidth and/or allow for up to two times data transfer rates between a processor chiplet (e.g., a GPU die) and the memory unit.

Additionally and/or optionally, by utilizing one or more TSVs that extend through a processor chiplet, the processor chiplet can access a memory unit located farther away (e.g., memory die(s) that are separated from the processor chiplet by another processor chiplet) through the RDL and the one or more TSVs. As such, latency associated with memories located farther away from the processor chiplet can be reduced compared with situations where the processor chiplet needs to access the memories through the other processor chiplet and additional bridge(s).

Further, by laterally disposing or positioning memory unit(s) around a periphery of a processor chiplet (rather than disposing the memory unit(s) vertically above the processor chiplet), heat generated by the processor chiplet can be better dissipated, thereby advantageously improving thermal management or thermal performance associated with the processor chiplet. In some embodiments, besides including a processor chiplet and a memory unit, a structure can optionally include a dummy device to further improve thermal performance associated with the structure. More specifically, the dummy device can include TSVs and/or highly thermal conductive materials and be disposed vertically directly above the processor chiplet (e.g., bonded to the processor chiplet) that is laterally spaced from the memory unit. A connecting element (e.g., a bridge) can be disposed vertically below the processor chiplet and the memory unit to electrically connect the processor chiplet and the memory unit. A RDL can be disposed vertically above the dummy device and the memory unit for electrically connecting the processor chiplet and the memory unit.

In some embodiments, the dummy device may not include any active circuitry (e.g., transistors), and may only include passive electronic components (e.g., capacitors, resistors, or the like) or no electrically functional components at all (e.g., the dummy device may be devoid of active circuitry and passive circuitry). The dummy device may help in managing heat generated by the processor chiplet (e.g., creating a thermal path that facilitates heat dissipation away from the processor chiplet). As such, the dummy device may advantageously prevent heat generated by the processor chiplet from being trapped and achieve efficient cooling of the processor chiplet. Additionally, the dummy device can ensure that a combined thickness of the processor chiplet and the dummy device equals or is approximately the same (e.g., above or below a thicknesses of the memory unit by less than 10%, less than 5%, less than 1%, or the like) as the thickness of the memory unit, creating a planar surface for disposing the RDL vertically above the dummy device and the memory unit. Advantageously, the dummy device can facilitate manufacturing (e.g., allows for flexibility in accommodating different heights and types of processor chiplets and memory units) of the structure, allowing for precise deposition and/or bonding of the RDL to electrically connect the processor chiplet and the memory unit.

Additionally and/or optionally, the processor chiplet, the memory unit, and/or the dummy device may be at least partially embedded in an encapsulant, where the RDL may be deposited over the encapsulant, the memory unit, and/or the dummy device. In some embodiments, the encapsulant can include organic material (e.g., a polymeric material like resin, epoxy molding compound, etc.) and/or inorganic material (e.g., silicon oxide, silicon nitride, etc.). The encapsulant may also include thermal conductive material (e.g., high-temperature epoxy molding materials) to further help in dissipating heat away from the processor chiplet. Optionally, the encapsulant can include one or multiple layers. In some embodiments, for example, the encapsulant can comprise multiple inorganic layers, e.g., a conformal silicon nitride layer and a filler silicon oxide layer disposed over the conformal silicon nitride layer. In other embodiments, the RDL can be hybrid bonded to the processor chiplet and the memory unit, instead of deposited over the encapsulant.

As used herein, the term “processor chiplet” (can also be referred to as “processor die”) can refer to least a central processing unit (CPU) die, a graphic processing unit (GPU) die, a neural networking processing unit (NPU) die, or a tensor processing unit (TPU) die. Multiple processor chiplets may be stitched or connected together to form a monolithic processor chip, such as a multicore GPU, a multicore CPU, a multicore NPU, a multicore TPU, or the like.

As used herein, high bandwidth memory (HBM) can refer to a type of dynamic random-access memory (DRAM) that is used in conjunction with high-performance computing systems. HBMs may provide high data transfer rates and low power consumption. HBM can allow for increased memory bandwidth and/or provide interface for memory access in applications or systems that include graphics processing units (GPUs), central processing units (CPUs), artificial intelligence (AI) accelerators, and/or the like. In some examples, a HBM can include a plurality of dies (e.g., a base logic die and multiple DRAM dies stacked upon the base logic die). To meet increasing demand for higher memory bandwidth and/or capacity, HBMs can include memory dies that are stacked on and connected to a controller circuit such as a processor die or a logic chip through some interconnect schemes (e.g., through substrate via or through silicon via (TSV)). For example, in existing semiconductor packages, multiple memory dies may be stacked above a logic chip or a controller chip that accesses the memory dies through TSVs. In some examples, HBM can support a bandwidth of greater than 250 gigabyte (GB) per stack. In some examples, HBM can support a bandwidth of greater than 400 GB per stack. In some examples, HBM can support a bandwidth of greater than 1000 GB per stack. In some examples, a HBM stack can have a memory bus that is wider than a memory bus of double data rate (DDR) or graphics double data rate (GDDR) memory devices, and can increase bandwidth, increase power efficiency, and/or lower memory latency. In some examples, a HBM stack can have a memory bus that has a width of 1024 bits or greater. In some examples, compared with DDR or GDDR memory devices, a HBM stack can operate at lower frequencies and voltages, while achieving higher data throughput. In some examples, a HBM stack can have a power efficient of 5 picojoules (pj) per bit transferred or less. In some examples, a HBM stack can have a power efficient of 4 pj/bit. In some examples, a HBM stack can have a power efficient of 3 pj/bit.

### Example Bonded Structures

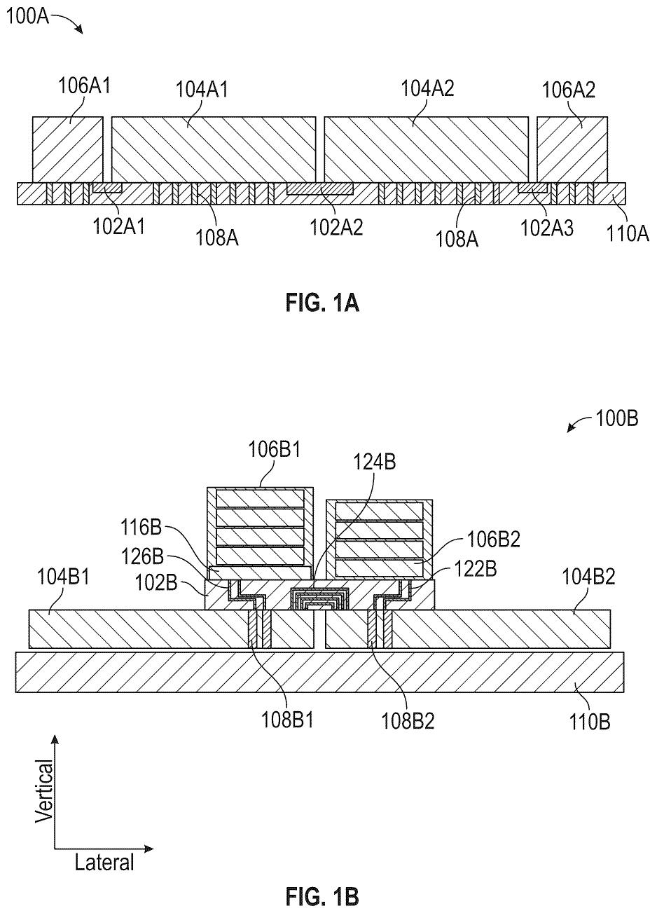

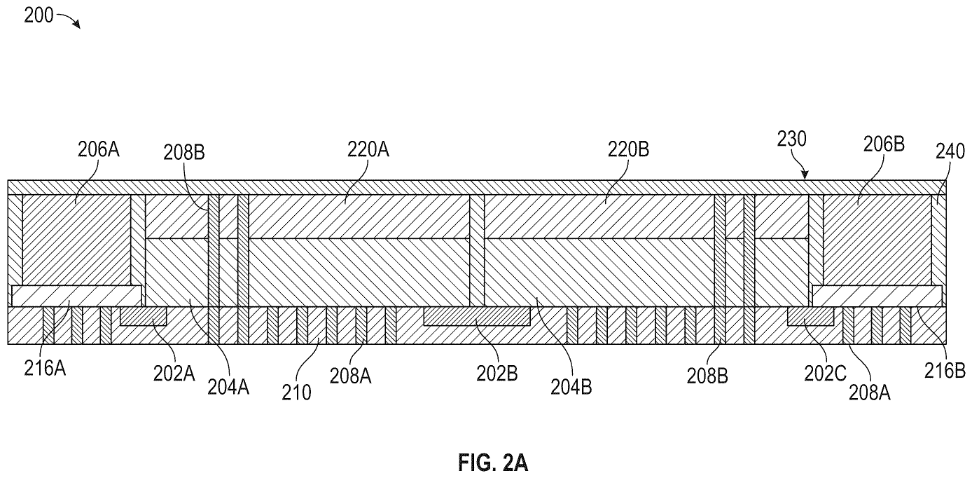

FIG. 1A illustrates a side schematic sectional view of a bonded structure 100A with high bandwidth memories stacked around a periphery of processor dies. The bonded structure 100A includes a bridge 102A1, a bridge 102A2, a bridge 102A3, a GPU die 104A1, a GPU die 104A2, a memory unit 106A1, a memory unit 106A2, vias 108A, and a substrate 110A. As shown in FIG. 1A, the memory units 106A1, 106A2 are positioned around the periphery of GPU dies 104A1, 104A2. The memory units 106A1, 106A2 and the GPU dies 104A1, 104A2 are shown to be mounted on a substrate 110A. The memory units 106A1, 106A2 and the GPU dies 104A1, 104A2 are electrically connected with each other through the bridges 102A1, 102A2, and 102A3. For example, the memory unit 106A1 can be electrically connected to the GPU die 104A1 through the bridge 102A1; the GPU die 104A1 can be electrically connected to the GPU die 104A2 through the bridge 102A2; and the GPU die 104A2 can be electrically connected to the memory unit 106A2 through the bridge 102A3. Each of the bridges 102A1, 102A2, and 102A3 can comprise routing layers (not shown) embedded in a dielectric as a part of the substrate 110A. Alternatively, each of the bridges 102A1, 102A2, and 102A3 can be an individual bridge die (e.g., a semiconductor or dielectric piece) embedded in a substrate (e.g., a ceramic, a printed circuit board (PCB), a semiconductor, or the like).

In some embodiments, the substrate 110A can be an organic substrate, a printed circuit board (PCB), a mold compound (e.g. fanout wafer/panel level reconstitution of bridge chips), an inorganic substrate, a semiconductor piece, or other types of substrate in which the bridges 102A1, 102A2, and 102A3 are at least partially embedded. The memory unit 106A1 may be laterally spaced from the GPU die 104A1, and may be connected to the GPU die 104A1 through transmission lines that include lateral conductive traces in routing layers of the bridge 102A1. The memory unit 106A2 may be laterally spaced from the GPU die 104A2, and may be connected to the GPU die 104A2 through transmission lines that include lateral conductive traces in routing layers of the bridge 102A3. A GPU die 104A1, a GPU die 104A2, a memory unit 106A1, and/or a memory unit 106A2 can also be mounted directly on a large silicon (or glass) interposer without the need of bridge chips; with high density connection routing between the memory units and GPU dies formed in the interposer. However, such large interposers (e.g. >60×60mm in footprint) can be cost prohibitive (due to significantly large area of silicon and/or bridges), add manufacturing complexities with low yield and introduce reliability challenges during assembly and operation (e.g. warpage).

Vias 108A extend vertically through the substrate 110A. The vias 108A may provide electrical connections for the memory units 106A1, 106A2 and the GPU dies 104A1, 104A2. The substrate 110A may provide structural support to the memory units 106A1, 106A2 and the GPU dies 104A1, 104A2. The substrate 110A may provide mechanical stability to the bonded structure 100A and accommodate the bridges 102A1, 102A2, and 102A3 to facilitate communication between the memory units and the GPU dies. An additional redistribution layer (RDL) can also be deposited on top of the substrate 110A to provide additional routing flexibility. RDL can also be formed at the bottom of the substrate 110A.

The implementations shown in FIG. 1A can suffer several drawbacks. First, a GPU die may not practically access a memory unit that is located farther from the GPU die because of high memory latency. For example, it may be unfeasible for the GPU die 104A2 to access the memory unit 106A1 because latency for data transfer between the GPU die 104A2 and the memory unit 106A1 may need to go through at least the bridge 102A1, the GPU die 104A1, and the bridge 102A2, which may be too high for certain applications. Second, a GPU die may only access a memory unit from the bottom of the memory unit, which can pose a bottleneck on communication between the GPU die and certain memory die(s). For example, the GPU die 104A1 may only access the memory unit 106A1 through the bridge 102A1 that is disposed vertically below the GPU die 104A1 and the memory unit 106A1. As such, latency between the GPU die 104A1 and a memory die on the top of the memory unit 106A1 may be longer than latency between the GPU die 104A1 and another memory die at the bottom of the memory unit 106A1, resulting in less efficient memory access associated with the memory die on the top of the memory unit 106A1.

FIG. 1B illustrates a side schematic sectional view of a bonded structure 100B with high bandwidth memories stacked above processor dies according to some implementations. The bonded structure 100B includes a connecting element 102B, processor dies 104B1, 104B2, memory units 106B1, 106B2, vias 108B1, 108B2, a substrate 110B, logic 116B, conductors 122B, 124B, 126B.

As shown in FIG. 1B, the substrate 110B can be a nonconductive or insulating base substrate with conductive routing traces (not shown) (e.g., at least partially embedded traces), such as a laminate substrate, a printed circuit board (PCB) substrate, a semiconductor interposer (e.g. silicon interposer), a glass interposer, a reconstituted structure with one or more die(s) at least partially embedded in an organic or inorganic encapsulant, a flexible substrate comprising a polymer with embedded traces, an integrated device die or wafer, or any other suitable substrate. The conductive routing traces can laterally and/or vertically transfer signals through the substrate 110B in various implementations, such as to connect to terminals on various sides of the substrate 110B, which in turn can be connected to a system board or other components within the larger electronic system.

The processor dies 104B1, 104B2 are shown to be disposed (e.g., bonded) on the substrate 110B. In some examples, the processor die 104B1 and/or the processor die 104B2 can be soldered to the substrate 110B or hybrid bonded to the substrate 110B if the substrate 110B has a bondable surface. The processor dies 104B1, 104B2 can be GPU dies, CPU dies, TPU dies, NPU dies, and/or any combination thereof. In some examples, each of the processor dies 104B1, 104B2 can be a GPU chiplet. The processor die 104B1 can include via 108B1 that facilitate data transfer within the processor die 104B1 and/or with other components of the bonded structure 100B. The processor die 104B2 can include via 108B2 that facilitate data transfer within the processor die 104B2 and/or with other components of the bonded structure 100B. For example, the via 108B1 may establish electrical connections among various layers of the processor die 104B1, and/or establish electrical connections with the connecting element 102B to facilitate communication between the processor die 104B1 and the memory units 106B1, 106B2. In some examples, the vias 108B1, 108B2 may be implemented as through-substrate-vias (TSVs) to provide passthrough that goes through the processor dies 104B1, 104B2. In these examples, the via 108B1 may provide communication between the connecting element 102B and the substrate 110B besides connecting various parts of the processor die 104B1. The via 108B2 may provide communication between the connecting element 102B and the substrate 110B besides connecting various parts of the processor die 104B2.

The connecting element 102B can be disposed (e.g., bonded (e.g., directly bonded) above the processor dies 104B1, 104B2. For example, the connecting element 102B can be hybrid bonded to each of the processor dies 104B1, 104B2. The connecting element 102B can provide at least electrical communication between one or more of the processor dies 104B1, 104B2, and one or more of the memory units 106B1, 106B2. For example, the connecting element 102B can connect the processor die 104B1 to either the memory unit 106B1 or the memory unit 106B2. As another example, the connecting element 102B can connect the processor die 104B1 to the memory unit 106B1 and the memory unit 106B2. As another example, the connecting element 102B can connect the processor die 104B2 to either the memory unit 106B1 or the memory unit 106B2. As still another example, the connecting element 102B can connect the processor die 104B1 to the processor die 104B2. As yet another example, the connecting element 102B can connect the first memory unit 106B1 to the second memory unit 106B2, and/or connect the processor dies 104B1, 104B2 to the memory unit 106B1 and the memory unit 106B2. The connecting element 102B can comprise one or more layers and materials for facilitating electrical communication. For example, the connecting element 102B can include one or more conductive layers that accommodate the conductors 122B, 124B, 126B. The conductors 122B, 124B, 126B may each include one or more vias (e.g., vertical electrical connections) and/or one or more traces (e.g., lateral electrical connections). In some implementations, a thickness or height (e.g., a length in a vertical direction) of the connecting element 102B can be around 3 micrometer (μm) to 300 μm. As such, a length of the conductors 122B, 124B, 126B (e.g., a vertical passthrough trace), may be as short as about 0.3 μm to 300 μm. In other implementations, the length of the conductors 122B 124B, 126B can be shorter than 0.3 μm or longer than 300 μm. For example, the length of a conductor in 122B, 124B and 126B can be less than 20 μm, or can be less than or more than 2 mm in situations where standard I/O blocks (e.g., the logic 116B) associated with the memory units 106B1 and 106B2 or the processor dies 104B1 and 104B2 are around 1 mm to 1.5 mm in the lateral direction.

The connecting element 102B can further include one or more dielectric layers (not shown) that surround the one or more conductive layers to provide electrical insulation and structural support. In some examples, the one or more dielectric layers can include inorganic layers, such as silicon oxide, silicon nitride, silicon oxynitride, silicon carbonitride, or any other dielectric that can form a hybrid bondable surface. Additionally or alternatively, the one or more dielectric layers can include one or more organic layers with bondable dielectric(s), such as inorganic dielectric, disposed over or under the organic layers. In some embodiments, the connecting element 102B can include an interposer, such as a semiconductor (e.g., silicon) interposer with vias and back-end-of-line (BEOL) layers on the top or the bottom of the silicon. In other embodiments, the connecting element 102B can include glass, ceramic, and/or other insulating substrate with embedded conductors. The connecting element 102B can additionally and/or optionally include one or more redistribution layers (RDL). The one or more RDL may be deployed on one or both sides (e.g., a first side of the connecting element 102B that is bonded to the processor dies 104B1, 104B2, and a second side of the connecting element 102B to which the memory units 106B1, 106B2 are bonded) of the connecting element 102B to allow the processor dies 104B1, 104B2 to access the memory units 106B1, 106B2. In some embodiments, the connecting element 102B may comprise passive elements such as resistors, capacitors, inductors, micro-electrical mechanical system (MEMS), optical elements, and/or the like. In some embodiments, the connecting element 102B may comprise an active (or functional) silicon (e.g. active bridge or active interposer). In some embodiments, a length of the connecting element 102B along the lateral direction (e.g., a width of the connecting element 102B) is at least longer than the length of a memory unit 106B1 and/or 106B2 along the lateral direction (e.g., a width of the memory unit 106B1).

The memory unit 106B1 can be disposed (e.g., bonded, such as directly bonded using hybrid bonding technique without adhesive or an intervening layer or flip chipped or micro-bumped) on the connecting element 102B to be vertically above the processor die 104B1. The memory unit 106B1 can comprise a plurality of (e.g., two, three, four, five, twelve, sixteen, or the like) memory dies (e.g., DRAM dies) hybrid bonded to and stacked on one another. Here, FIG. 1B illustrates a non-limiting example of the memory unit 106B1 having four memory dies. The memory dies of the memory unit 106B1 may communicate with the base die or logic 116B of the memory unit 106B1. The logic 116B can be a logic die or controller die, and can include various logic (e.g., input/output (I/O) interface logic) to facilitate communications between memory dies of the memory unit 106B1 and the processor dies 104B1, 104B2. For example, the logic 116B can manage data communicated to or from the stack of memory dies (e.g., data sent to and/or received from the processor dies 104B1, 104B2, or other devices) of the memory unit 106B1. Although not shown, TSVs can extend through the memory dies of the memory unit 106B1 to provide communication with the logic 116B. Further, the logic die and/or memory unit 106B1 can be encapsulated by one or more encapsulants, such as inorganic dielectric (e.g., silicon oxide, silicon nitride, etc.) or an organic dielectric (e.g., a polymeric material like resin, epoxy molding compound, etc.).

The memory unit 106B2 can be disposed (e.g., bonded, such as directly bonded using hybrid bonding technique without adhesive or an intervening layer) on the connecting element 102B to be vertically above the processor die 104B2. The memory unit 106B2 may include components the same as or similar to those described above with regard to the memory unit 106B1. Here, FIG. 1B illustrates a non-limiting example of the memory unit 106B2 having four memory dies but without a logic controller die, in contrast to the memory unit 106B1. In some examples, although not illustrated in FIG. 1B, a logic controller die (e.g., the logic 116B) can be integrated as a part of the connecting element 102B to facilitate communications between memory dies of the memory unit 106B2 and the processor dies 104B1, 104B2. As such, in some examples, the connecting element 102B can be a passive interconnect element. In other examples, the connecting element 102B can further comprise a semiconductor element with active circuitry (e.g., a logic controller for one or more memory units, cache (e.g. L1, L2, L3 cache), network on chip (NOC), switch chip (e.g. network switch), accelerator fabric links, IO interfaces, PCIe express, HBM interface, fuse, photonic IC, laser, photodiode, etc.) and passive circuitry (e.g., capacitors, resistors, inductors, or the like). Although FIG. 1B illustrates two memory units 106B1, 106B2 disposed above the connecting element 102B, it should be noted that in some implementations there may be more or fewer memory units disposed above the connecting element 102B. For example, the bonded structure 100B may include the memory unit 106B1 without including the memory unit 106B2, or vice versa. In some examples, each of the memory units 106B1 and 106B2 can include four, eight, twelve, sixteen, or other number of memory dies. For example, each of the memory units 106B1 and 106B2 may include eight memory dies such that the memory units 106B1 and 106B2 include sixteen memory dies. Advantageously, the number of memory dies accessible to the processor die 104B1 and/or the processor die 104B2 via a controller die (e.g., the logic 116B) can be increased (e.g., doubled). In some examples, the number of memory dies in a memory stack or a memory unit (e.g., the memory unit 106B1 or 106B2) can be limited to be below certain number, thereby increasing yield associated with the bonded structure 100B.

In some examples, the processor dies 104B1, 104B2 are laterally spaced from each other. The memory unit 106B1 is disposed vertically above the processor die 104B1. The memory unit 106B2 is disposed vertically above the processor die 104B2. The connecting element 102B is disposed vertically between the memory unit 106B1 and the processor die 104B1, and vertically between the memory unit 106B1 and the processor die 104B2. The connecting element 102B includes the conductors 122B, 124B, 126B. The conductor 124B electrically connects the processor dies 104B1, 104B2. The conductor 126B electrically connects the processor die 104B1 and the memory unit 106B1. The memory unit 106B1 may include a stack of memory dies (e.g., four memory dies) and the logic 116B stacked below the stack of memory dies. The processor die 104B1 may communicate with the memory unit 106B1 at least through the conductor 126B. The processor die 104B2 may communicate with the memory unit 106B1 at least through the conductors 126B, 124B. It should be noted that the processor die 104B1, the processor die 104B2, the memory unit 106B1, and/or the memory unit 106B2 can be bonded face down. The connecting element 102B, if including active circuitry, can be bonded face down or face up.

In some examples, the memory unit 106B2 may be disposed vertically above the processor die 104B2. The memory unit 106B2 may be laterally spaced from the memory unit 106B1. The connecting element 102B may be disposed vertically between the memory unit 106B2 and the processor die 104B1, and vertically between the memory unit 106B2 and the processor die 104B2. The connecting element 102B may include the conductor 122B that electrically connects the processor die 104B2 and the memory unit 106B2. The processor die 104B1 may communicate with the memory unit 106B2 at least through the conductors 122B, 124B.

Although the bonded structure 100B may decrease memory latency between a processor die and a memory unit located farther away from the processor die by disposing the memory unit vertically above the processor die, the implementations shown in FIG. 1B can still suffer some limitations. First, the memory units 106B1 and 106B2 may only be accessed by the processor dies 104B1 and/or 104B2 through the bottom, which may pose a bottleneck on data transfer rate and/or leading to longer memory latency associated with memory dies disposed toward the top of the memory units 106B1 and 106B2. Additionally, disposing the memory units 106B1 and 106B2 directly above the processor dies 104B1 and 104B2 can impede effective heat dissipation. For example, some of the heat generated by the processor die 104B1 may need to pass through the memory units 106B1 and 106B2 to be dissipated, which can lead to the heat being trapped or blocked from effective dissipation. As such, it can be difficult for the bonded structure 100B utilizing the connecting element 102B to manage and dissipate heat effectively, potentially affecting the performance and reliability of the bonded structure 100B.

As noted above, some implementations disclosed herein can enable high bandwidth and/or high data rate communications between processor dies and memory units without compromising thermal performance by using one or more connecting elements (e.g., a redistribution layer (RDL), through-substrate-vias (TSVs), and/or the like) to allow a processor die to access a memory unit both from top and bottom of the memory unit.

### Example Bonded Structures

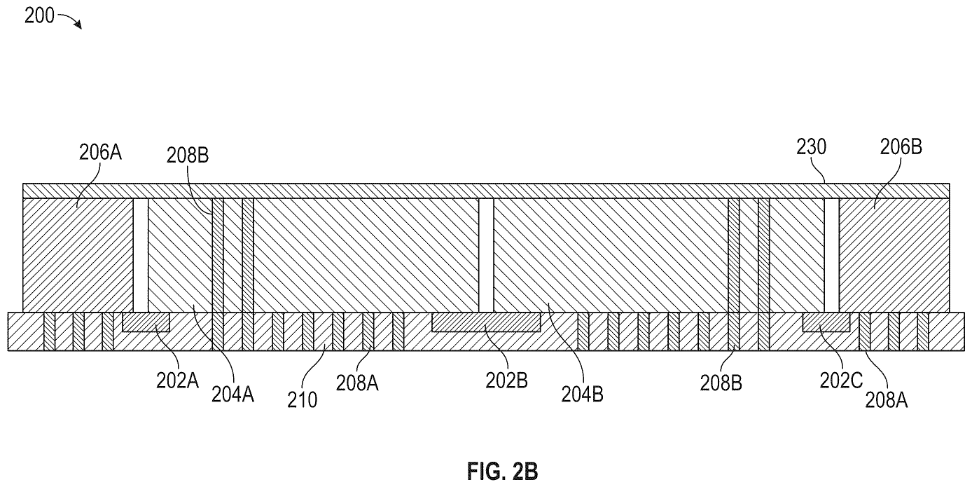

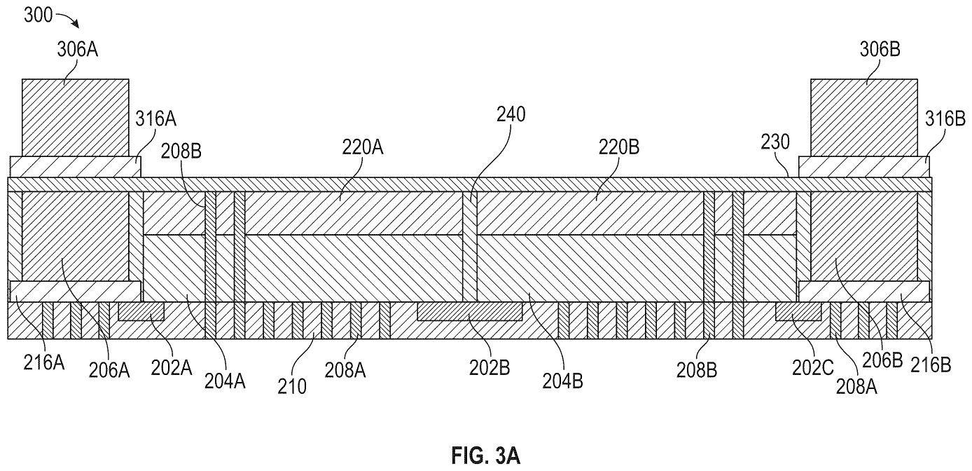

FIG. 2A illustrates a side schematic sectional view of an example implementation of a bonded structure 200 with high bandwidth memories stacked around a periphery of processor dies according to some embodiments. Unless otherwise noted, the components of FIG. 2A can be the same as or generally similar to like-numbered components of FIG. 1A and FIG. 1B. As illustrated in FIG. 2A, the bonded structure 200 includes a bridge 202A, a bridge 202B, a bridge 202C, a processor die 204A, a processor die 204B, a memory unit 206A, a memory unit 206B, vias 208A, vias 208B, a substrate 210, controller logic 216A, controller logic 216B, a dummy device 220A, a dummy device 220B, a RDL 230, and encapsulant 240. The substrate may comprise of silicon or glass or ceramic or organic substrate or interposer. In some embodiments, the substrate may comprise of organic or inorganic package and combinations thereof.

In some embodiments, the memory unit 206A can include a stack of memory dies (e.g., a plurality of DRAM dies). The memory unit 206A is laterally spaced from the processor die 204A, and is at least electrically connected to the processor die 204A through the controller logic 216A and the bridge 202A. The controller logic 216A can be disposed vertically below the memory unit 206A, enabling communication between the memory unit 206A and the processor die 204A. In other embodiments, the controller logic 216A can also be disposed vertically above the memory unit 206A, or be disposed only vertically above or below the memory unit 206A. The memory unit 206B, similar to the memory unit 206A, can include a stack of memory dies, and can be laterally spaced from and electrically connected to the processor die 204B through the controller logic 216B and the bridge 202C. The controller logic 216B can be disposed vertically below the memory unit 206B, enabling communication between the memory unit 206B and the processor die 204B. In other embodiments, the controller logic 216B can also be disposed vertically above the memory unit 206B, or be disposed only vertically above or below the memory unit 206B.

In some embodiments, the controller logic 216A can manage data communicated to or from the memory unit 206A (e.g., data sent to and/or received from the processor dies 204A, 204B, or other devices). Although not shown, TSVs can extend through the memory dies of the memory unit 206A to provide communication with the controller logic 216A. The controller logic 216B can manage data communicated to or from the memory unit 206B (e.g., data sent to and/or received from the processor dies 204A, 204B, or other devices). Although not shown, TSVs can extend through the memory dies of the memory unit 206B to provide communication with the controller logic 216B. It should be noted that the controller logic 216A and/or the controller logic 216B can be optional to the bonded structure 200. In other embodiments, the controller logic 216A can be integrated as a part of the memory unit 206A, and the controller logic 216B can be integrated as a part of the memory unit 206B.

As shown in FIG. 2A, the dummy device 220A is disposed (e.g., through direct bonding or adhesive) vertically directly above the processor die 204A. The dummy device 220A may or may not include any active circuitry and may help managing heat (e.g., through TSVs and/or thermal conductive material within the dummy device 220A) generated by the processor die 204A and/or may provide structural support to the processor die 204A. The dummy device 220A can ensure that the combined thickness of the processor die 204A and the dummy device 220A equals or is approximately the same as the thickness of the memory unit 206A and the controller logic 216A, thereby creating a planar surface for disposing the RDL 230 above the memory unit 206A and the processor die 204A. The dummy device 220B is disposed vertically directly above the processor die 204B. The dummy device 220B may or may not include any active circuitry and may help managing heat generated by the processor die 204B and/or may provide structural support to the processor die 204A. The dummy device 220B can ensure that the combined thickness of the processor die 204B and the dummy device 220B equals or is approximately the same as the thickness of the memory unit 206B and the controller logic 216B, thereby creating a planar surface for disposing the RDL 230 above the memory unit 206B and the processor die 204B. Advantageously, the dummy devices 220A and 220B can include TSVs and/or highly thermal conductive materials, and can be used to provide structural support, manage thermal issues, balance layout, or ensure uniformity in the manufacturing process of the bonded structure 200.

In some embodiments, the vias 208A can extend vertically through the substrate 210. The vias 208A may provide electrical connections for the memory units 206A, 206B and the processor dies 204A, 204B. The vias 208B may be implemented as through-substrate-vias (TSVs) to provide passthrough that goes through the processor dies 204A, 204B.

The RDL 230 can be disposed vertically above the dummy devices 220A, 220B and the memory units 206A, 206B. The RDL 230 can electrically connect the processor dies 204A and 204B to the memory units 206A and 206B. The RDL 230 can allow the processor dies 204A and 204B to access the memory units 206A and 206B both from the top and bottom, effectively increasing the memory bandwidth and enabling up to two times data transfer rates between the processor dies 204A and 204B and the memory units 206A and 206B. For example, the processor die 204A can access the memory unit 206A from the bottom of the memory unit 206A through the bridge 202A, and can access the memory unit 206A from the top through the RDL 230 and the vias 208B. As another example, the processor die 204A may access the memory unit 206B at least through the RDL 230 and the vias 208B.

In some embodiments, at least some of the processor dies 204A, 204B, memory units 206A, 206B, controller logic 216A, 216B, dummy devices 220A, 220B, the RDL 230 can be disposed using hybrid bonding. For example, the processor die 204A and/or the processor die 204B can be hybrid bonded to the substrate 210. As another example, the controller logic 216A and/or the controller logic 216B can be hybrid bonded to the substrate 210. As another example, the memory unit 206A can be hybrid bonded to the controller logic 216A. As another example, the memory unit 206B can be hybrid bonded to the controller logic 216B. As yet another example, memory dies within the memory unit 206A and/or memory unit 206B can be hybrid bonded with each other. As still another example, the dummy device 220A can be directly bonded to the processor die 204A, and/or the dummy device 220B can be directly bonded to the processor die 204B.

In some embodiments, the processor dies 204A, 204B, and/or the memory units 206A, 206B, the dummy devices 220A and 220B can be optionally reconstituted or encapsulated using the encapsulant 240. Although not illustrated in FIG. 2A, the unwanted portions of the encapsulant 240 can be removed and/or planarized. In some embodiments, backside vias (not shown in FIG. 2A) of the memory units 206A, 206B, the dummy devices 220A and 220B are revealed prior to the formation of the RDL 230 over the revealed vias. In other embodiments, the RDL 230 can be hybrid bonded by way of a transfer process to a planarized smooth backside bonding surface comprised of backside vias of the memory units 206A, 206B, the dummy devices 220A and 220B.

In some embodiments, for example, the RDL 230 may be formed over a temporary carrier (not shown in FIG. 2A), and hybrid bonded to the processor dies 204A, 204B, and the memory units 206A, 206B, before the temporary carrier is removed.

The encapsulant 240 can at least partially embed the processor dies 204A and 204B, the memory units 206A and 206B, and/or the dummy devices 220A and 220B. The encapsulant 240 can include thermal conductive material, such as high-temperature epoxy molding materials containing conductive particles, to help dissipate heat away from the processor dies 204A and 204B. In some embodiments, the encapsulant 240 can include organic material (e.g., a polymeric material like resin, epoxy molding compound, etc.) and/or inorganic material (e.g., silicon oxide, silicon nitride, etc.). The encapsulant 240 may provide additional structural support and/or protection to the bonded structure 200.

It should be noted that, in other embodiments, the bonded structure 200 may not include the dummy device 220A and/or the dummy device 220B. In these embodiments, the RDL 230 may be disposed vertically directly above the memory units 206A, 206B, and the processor dies 204A, 204B. For example, FIG. 2B shows another implementation of the bonded structure 200. Unless otherwise noted, the components of FIG. 2B can be the same as or generally similar to like-numbered components of FIG. 2A. As shown in FIG. 2B, the bonded structure 200 includes a bridge 202A, a bridge 202B, a bridge 202C, a processor die 204A, a processor die 204B, a memory unit 206A, a memory unit 206B, vias 208A, vias 208B, a substrate 210, and a RDL 230. In contrast to the implementation of FIG. 2A, the bonded structure 200 shown in FIG. 2B does not include dummy device(s) (e.g., the dummy devices 220A, 220B shown in FIG. 2A). Further, the bonded structure 200 shown in FIG. 2B does may or may not include encapsulant 240. It should also be noted that the bonded structure 200 shown in FIG. 2B does not include controller logic(s) (e.g., the controller logic 216A, 216B shown in FIG. 2A).

In contrast to the implementations of FIG. 1A and FIG. 1B, the bonded structure 200 offers several advantages. First, by disposing the RDL 230 vertically above the processor dies 204A, 204B, and the memory units 206A, 206B, the processor dies 204A, 204B may access the memory units 206A, 206B both from top and bottom, which can double memory bandwidth and/or allow for up to two times data transfer rates between the processor dies 204A, 204B, and the memory units 206A, 206B. For example, the processor die 204B may access the memory unit 206B from the top through the RDL 230 and the vias 208B, and may access the memory unit 206B from the bottom at least through the bridge 202C. Second, the processor die 204A and/or the processor die 204B may access a memory unit that is located farther away at least through the RDL 230 and the vias 208B. For example, the processor die 204B may access the memory unit 206A from the top through the RDL 230 and the vias 208B. Third, by laterally disposing or positioning memory units 206A, 206B around peripheries of the processor dies 204A, 204B (rather than disposing the memory units 206A, 206B vertically above the processor dies 204A, 204B), heat generated by the processor dies 204A, 204B can be more effectively dissipated compared with the implementations of FIG. 1B, thereby advantageously improving thermal management or thermal performance associated with the processor dies 204A, 204B. Additionally, by laterally disposing the memory units 206A, 206B around peripheries of the processor dies 204A, 204B, cooling device(s) (not shown in FIG. 2A) may also be optionally disposed vertically above the processor dies 204A, 204B (besides disposing the dummy devices 220A, 220B above the processor dies 204A, 204B) to improve thermal performance of the bonded structure 200.

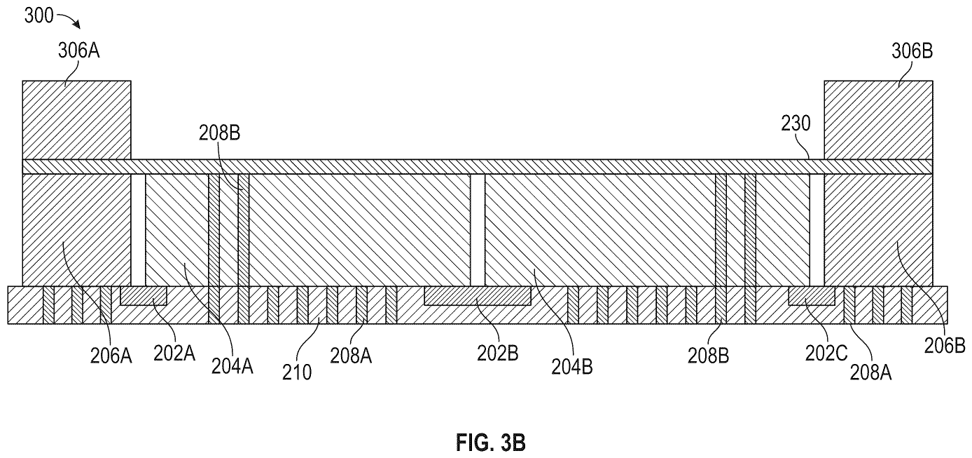

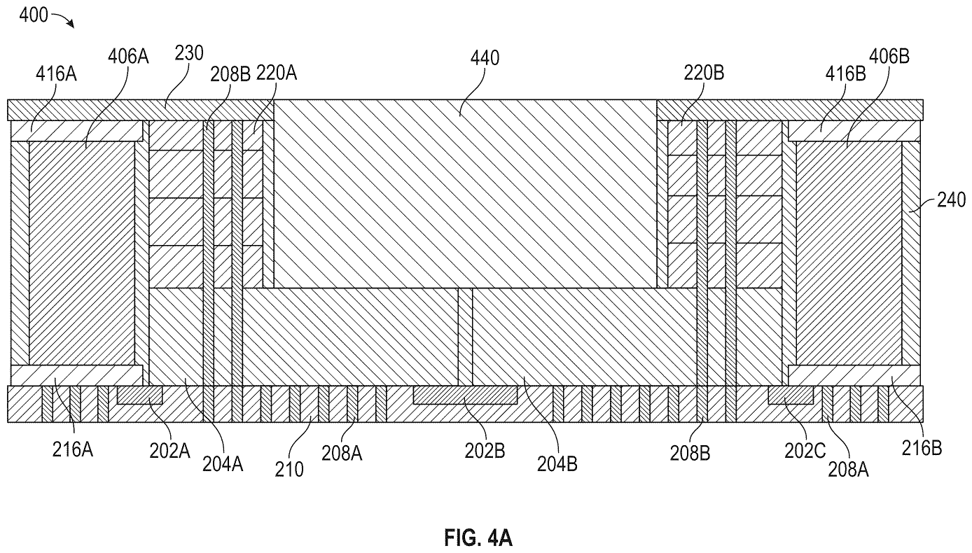

FIG. 3A illustrates a side schematic sectional view of an example implementation of a bonded structure 300 with high bandwidth memories stacked around a periphery of processor dies according to some embodiments. Unless otherwise noted, the components of FIG. 3A can be the same as or generally similar to like-numbered components of FIG. 1A, FIG. 1B, and FIG. 2A. As illustrated in FIG. 3A, the bonded structure 300 includes a bridge 202A, a bridge 202B, a bridge 202C, a processor die 204A, a processor die 204B, a memory unit 206A, a memory unit 206B, vias 208A, vias 208B, a substrate 210, controller logic 216A, controller logic 216B, a dummy device 220A, a dummy device 220B, a RDL 230, encapsulant 240, memory unit 306A, controller logic 316A, memory unit 306B, and controller logic 316B.

In contrast to the implementations in FIG. 2A, the bonded structure 300 further includes the memory unit 306A, the controller logic 316A, the memory unit 306B, and the controller logic 316B. As shown in FIG. 3A, the memory unit 306A, the controller logic 316A, the memory unit 306B, the controller logic 316B are disposed above the RDL 230. The controller logic 316A is disposed below the memory unit 306A. The controller logic 316B is disposed below the memory unit 306B.

In some embodiments, at least through the RDL 230, the processor dies 204A, 204B can not only communicate with the memory units 206A, 206B but the memory units 306A, 306B. For example, the processor die 204A can communicate with the memory unit 306A through the vias 208B, the RDL 230, and the controller logic 316A. As another example, the processor die 204B can communicate with the memory unit 306B through the vias 208B, the RDL 230, and the controller logic 316B. As yet another example, the processor die 204A can communicate with the memory unit 306B through the vias 208B, the RDL 230, and the controller logic 316B.

Although not illustrated in FIG. 3A, in some embodiments, a dummy thermal structure (e.g., a cooling device) can be disposed vertically above the processor dies 204A, 204B, and laterally between the memory units 306A, 306B. Advantageously, the cooling device can further enhance thermal performance of the bonded structure 300 by facilitating dissipation of heat generated by the processor dies 204A, 204B.

FIG. 3B illustrates a side schematic sectional view of another example implementation of a bonded structure 300. Unless otherwise noted, the components of FIG. 3B can be the same as or generally similar to like-numbered components of FIG. 3A. As shown in FIG. 3B, the bonded structure 300 includes a bridge 202A, a bridge 202B, a bridge 202C, a processor die 204A, a processor die 204B, a memory unit 206A, a memory unit 206B, vias 208A, vias 208B, a substrate 210, a RDL 230, memory unit 306A, and memory unit 306B. In contrast to the implementation of FIG. 3A, the bonded structure 300 shown in FIG. 3B does not include dummy device(s) (e.g., the dummy devices 220A, 220B shown in FIG. 3A). Further, the bonded structure 300 shown in FIG. 3B may or may not include encapsulant 240. It should be noted that the bonded structure 200 shown in FIG. 2B does not include controller logic (e.g., the controller logic 216A, 216B, 316A, and 316B shown in FIG. 3A).

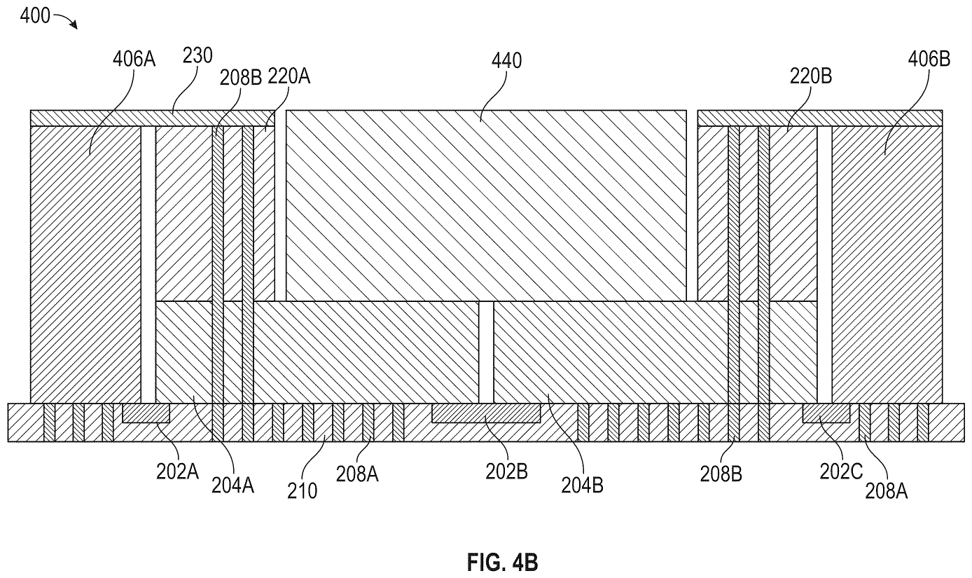

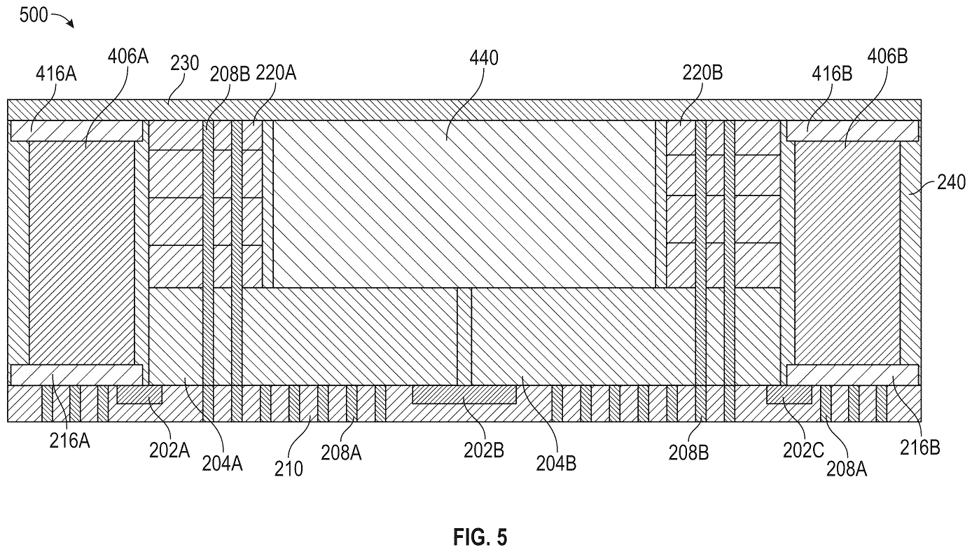

FIG. 4A illustrates a side schematic sectional view of an example implementation of a bonded structure 400 with high bandwidth memories stacked around a periphery of processor dies according to some embodiments. Unless otherwise noted, the components of FIG. 4A can be the same as or generally similar to like-numbered components of FIGS. 1A, 1B, 2, and 3. As illustrated in FIG. 4A, the bonded structure 400 includes a bridge 202A, a bridge 202B, a bridge 202C, a processor die 204A, a processor die 204B, vias 208A, vias 208B, a substrate 210, controller logic 216A, controller logic 216B, a memory unit 406A, a memory unit 406B, controller logic 416A, controller logic 416B, dummy devices 220A, dummy devices 220B, a RDL 230, encapsulant 240, and a cooling device 440.

In contrast to the implementations in FIGS. 2 and 3, the bonded structure 400 includes multiple dummy devices (e.g., the dummy devices 220A and the dummy devices 220B) to flexibly accommodate increased height (e.g., compared with height of the memory units 206A, 206B) associated with the memory units 406A and 406B. For example, a combined thickness of the dummy devices 220A and the processor die 204A may equal a combined thickness of the memory unit 406A, the controller logic 216A, and the controller logic 416A to provide a planar surface for disposing the RDL 230. Additionally, the bonded structure 400 further includes the cooling device 440 to dissipate heat generated by the processor dies 204A, 204B, thereby improving thermal performance of the bonded structure 400. In some embodiments, the dummy devices 220A can be directly bonded with each other. In some embodiments, the dummy devices 220B can be directly bonded with each other. In some embodiments, the cooling device 440 can be directly bonded to the processor die 204A and the processor die 204B. In other embodiments, the cooling device 440 can be adhered or directly bonded to the processor die 204A and the processor die 204B with thermally conductive adhesive. In some embodiments, the cooling device 440 can comprise semiconductor material with conductors to convey heat away. In other embodiments, the cooling device 440 can include liquid pathways or cavities therein to convey heat away from the processor die 204A and the processor die 204B. Although not illustrated in FIG. 4A, it should be noted that in some embodiments, the dummy devices 220A can be replaced by a single dummy device, and/or the dummy devices 220B can be replaced by another single dummy device.

As shown in FIG. 4A, in some embodiments, the RDL 230 may not be disposed above the cooling device 440. Although not readily observed from FIG. 4A, the RDL 230 may not be disposed vertically above the cooling device 440, and may or may not bypass the cooling device 440 to form an integral or unity structure (e.g., an annular or donut-shaped structure) where the portion of the RDL 230 disposed vertically above the memory unit 406A and the portion of the RDL 230 disposed vertically above the memory unit 406B are electrically connected. Advantageously, the RDL 230 can still allow, for example, the processor die 204A to access (e.g., through the vias 208B, the RDL 230, the controller logic 416B) the memory unit 406B without needing to dispose the RDL 230 above the cooling device 440. It should be noted that, in the example implementation of FIG. 4A, there may be an air gap (not shown) between the RDL 230 and the cooling device 440. The cooling device 440 may comprise of directly bonded multiple thermally conductive elements.

FIG. 4B illustrates a side schematic sectional view of another example implementation of a bonded structure 400. Unless otherwise noted, the components of FIG. 4B can be the same as or generally similar to like-numbered components of FIG. 4A. As shown in FIG. 4B, the bonded structure 400 includes a bridge 202A, a bridge 202B, a bridge 202C, a processor die 204A, a processor die 204B, vias 208A, vias 208B, a substrate 210, a memory unit 406A, a memory unit 406B, a dummy device 220A, a dummy device 220B, a RDL 230, and a cooling device 440. In contrast to the implementation of FIG. 4A, the bonded structure 400 shown in FIG. 4B includes a dummy device 220A (e.g., a single dummy device rather than multiple dummy devices 220A shown in FIG. 4A), and a dummy device 220B (e.g., a single dummy device rather than multiple dummy devices 220B shown in FIG. 4B). Further, the bonded structure 400 shown in FIG. 4B may or may not include encapsulant 240. It should be noted that the bonded structure 400 shown in FIG. 4B does not include controller logic (e.g., the controller logic 216A, 216B, 416A, and 416B shown in FIG. 4A). In some embodiments, the controller logic can be integrated into the memory units 406A and 406B. In some embodiments, the conductive vias 208B disposed in the dummy device 220A may comprise of vias having incompletely filled conductive layer. For example, the outer portion of the vias may comprise of a conformal or nonconformal coating of conductive material, while the inner portion (inner diameter portion) may be voided of or filled with a different material. The different material may comprise of a conductive or nonconductive material.

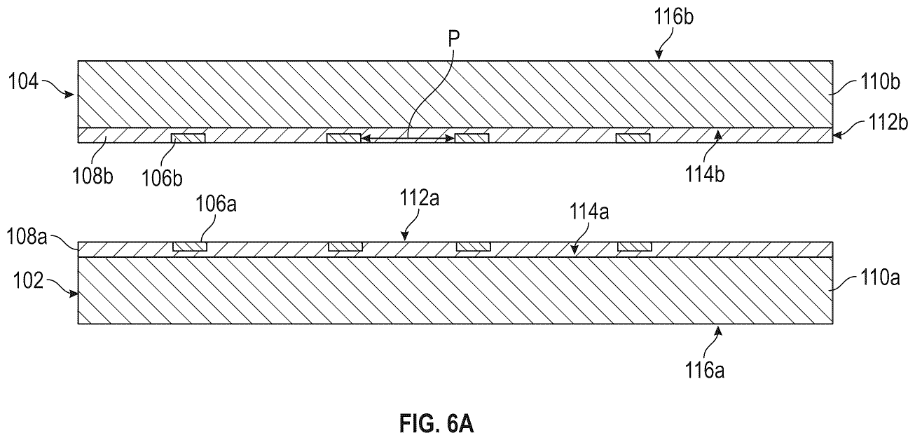

FIG. 5 illustrates a side schematic sectional view of an example implementation of a bonded structure 500 with high bandwidth memories stacked around a periphery of processor dies according to some embodiments. Unless otherwise noted, the components of FIG. 5 can be the same as or generally similar to like-numbered components of FIGS. 1A, 1B, 2, 3, and 4. As illustrated in FIG. 5, the bonded structure 500 includes a bridge 202A, a bridge 202B, a bridge 202C, a processor die 204A, a processor die 204B, vias 208A, vias 208B, a substrate 210, controller logic 216A, controller logic 216B, a memory unit 406A, a memory unit 406B, controller logic 416A, controller logic 416B, dummy devices 220A, dummy devices 220B, a RDL 230, encapsulant 240, and a cooling device 440.

In contrast to the implementations of FIG. 4A, the RDL 230 in the bonded structure 500 is disposed vertically above the cooling device 440, besides disposed above the processor die 204A, the processor die 204B, the memory unit 406A, and the memory unit 406B.

In some embodiments, the encapsulant 240 can comprise one or multiple inorganic dielectric layers (e.g., silicon oxide, silicon nitride, or the like). The one or more inorganic layers can comprise a first thin conformal layer (e.g., silicon nitride) and a second filling layer (e.g., silicon oxide). In other implementations, the encapsulant 240 can comprise one or multiple organic layers (e.g., molding compound, resin, epoxy, or the like), with a bondable surface on top (e.g., an inorganic dielectric disposed on the organic layer(s)).

In some embodiments, the processor dies 204A, 204B, the memory units 406A, 406B, and/or the dummy devices 220A, 220B may be at least partially embedded in the encapsulant 240. The RDL 230 may be deposited over the encapsulant 240, the memory units 406A, 406B, and/or the dummy devices 220A, 220B. In other embodiments, the RDL 230 can be hybrid bonded (e.g., by way of a transfer process utilizing a carrier) to the processor dies 204A, 204B, the memory units 406A, 406B, the dummy devices 220A, 220B. In some embodiments, after the fabrication of structures 200 or 300 or 400 or 500 and combinations thereof on a large substrate (silicon wafer, glass wafer or panel, ceramic wafer or panel, etc.) the formed structures may be coated with a protective layer prior to singulation to their appropriate sizes. The protective layer is stripped off from the singulated structure and the substrate layer 210 may be bond to another structure by hybrid bonding method or via flowable contacts such as micro bumps, solders, C4 and their like.

### Direct Bonding

Various embodiments disclosed herein relate to directly bonded structures in which two or more elements can be directly bonded to one another without an intervening adhesive. Such processes and structures are referred to herein as “direct bonding” processes or “directly bonded” structures. Direct bonding can involve bonding of one material on one element and one material on the other element (also referred to as “uniform” direct bond herein), where the materials on the different elements need not be the same, without traditional adhesive materials. Direct bonding can also involve bonding of multiple materials on one element to multiple materials on the other element (e.g., hybrid bonding).

In some implementations (not illustrated), each bonding layer has one material. In these uniform direct bonding processes, only one material on each element is directly bonded. Example uniform direct bonding processes include the ZIBOND® techniques commercially available from Adeia of San Jose, CA. The materials of opposing bonding layers on the different elements can be the same or different, and may comprise elemental or compound materials. For example, in some embodiments, nonconductive bonding layers can be blanket deposited over the base substrate portions without being patterned with conductive features (e.g., without pads). In other embodiments, the bonding layers can be patterned on one or both elements, and can be the same or different from one another, but one material from each element is directly bonded without adhesive across surfaces of the elements (or across the surface of the smaller element if the elements are differently-sized). In another implementation of uniform direct bonding, one or both of the nonconductive bonding layers may include one or more conductive features, but the conductive features are not involved in the bonding. For example, in some implementations, opposing nonconductive bonding layers can be uniformly directly bonded to one another, and through substrate vias (TSVs) can be subsequently formed through one element after bonding to provide electrical communication to the other element.

In various embodiments, the bonding layers 108a and/or 108b can comprise a non-conductive material such as a dielectric material or an undoped semiconductor material, such as undoped silicon, which may include native oxide. Suitable dielectric bonding surface or materials for direct bonding include but are not limited to inorganic dielectrics, such as silicon oxide, silicon nitride, or silicon oxynitride, or can include carbon, such as silicon carbide, silicon oxycarbonitride, low K dielectric materials, SiCOH dielectrics, silicon carbonitride or diamond-like carbon or a material comprising a diamond surface. Such carbon-containing ceramic materials can be considered inorganic, despite the inclusion of carbon. In some embodiments, the dielectric materials at the bonding surface do not comprise polymer materials, such as epoxy (e.g., epoxy adhesives, cured epoxies, or epoxy composites such as FR-4 materials), resin or molding materials.

In other embodiments, the bonding layers can comprise an electrically conductive material, such as a deposited conductive oxide material, e.g., indium tin oxide (ITO), as disclosed in U.S. Provisional Patent Application No. 63/524,564, filed Jun. 30, 2023, the entire contents of which is incorporated by reference herein in its entirety for providing examples of conductive bonding layers without shorting contacts through the interface.

In direct bonding, first and second elements can be directly bonded to one another without an adhesive, which is different from a deposition process and results in a structurally different interface compared to that produced by deposition. In one application, a width of the first element in the bonded structure is similar to a width of the second element. In some other embodiments, a width of the first element in the bonded structure is different from a width of the second element. The width or area of the larger element in the bonded structure may be at least 10% larger than the width or area of the smaller element. Further, the interface between directly bonded structures, unlike the interface beneath deposited layers, can include a defect region in which nanometer-scale voids (nanovoids) are present. The nanovoids may be formed due to activation of one or both of the bonding surfaces (e.g., exposure to a plasma, explained below).

The bond interface between non-conductive bonding surfaces can include a higher concentration of materials from the activation and/or last chemical treatment processes compared to the bulk of the bonding layers. For example, in embodiments that utilize a nitrogen plasma for activation, a nitrogen concentration peak can be formed at the bond interface. In some embodiments, the nitrogen concentration peak may be detectable using secondary ion mass spectroscopy (SIMS) techniques. In various embodiments, for example, a nitrogen termination treatment (e.g., exposing the bonding surface to a nitrogen-containing plasma) can replace OH groups of a hydrolyzed (OH-terminated) surface with NH₂ molecules, yielding a nitrogen-terminated surface. In embodiments that utilize an oxygen plasma for activation, an oxygen concentration peak can be formed at the bond interface between non-conductive bonding surfaces. In some embodiments, the bond interface can comprise silicon oxynitride, silicon oxycarbonitride, or silicon carbonitride. The direct bond can comprise a covalent bond, which is stronger than van Der Waals bonds. The bonding layers can also comprise polished surfaces that are planarized to a high degree of smoothness.

In direct bonding processes, such as uniform direct bonding and hybrid bonding, two elements are bonded together without an intervening adhesive. In non-direct bonding processes that utilize an adhesive, an intervening material is typically applied to one or both elements to effectuate a physical connection between the elements. For example, in some adhesive-based processes, a flowable adhesive (e.g., an organic adhesive, such as an epoxy), which can include conductive filler materials, can be applied to one or both elements and cured to form the physical (rather than chemical or covalent) connection between elements. Many organic adhesives lack strong chemical or covalent bonds with either element. In such processes, the connections between the elements are weak and/or readily reversed, such as by reheating.

By contrast, direct bonding processes join two elements by forming strong chemical bonds (e.g., covalent bonds) between opposing nonconductive materials. For example, in direct bonding processes between nonconductive materials, one or both nonconductive surfaces of the two elements are planarized and chemically prepared (e.g., activated and/or terminated) such that when the elements are brought into contact, strong chemical bonds (e.g., covalent bonds) are formed, which are stronger than Van der Waals or hydrogen bonds. In some implementations (e.g., between opposing dielectric surfaces, such as opposing silicon oxide surfaces), the chemical bonds can occur spontaneously at room temperature upon being brought into contact. In some implementations, the chemical bonds between opposing non-conductive materials can be strengthened after annealing the elements.

As noted above, hybrid bonding is a species of direct bonding in which both non-conductive features directly bond to non-conductive features, and conductive features directly bond to conductive features of the elements being bonded. The non-conductive bonding materials and interface can be as described above, while the conductive bond can be formed, for example, as a direct metal-to-metal connection. In one example metal bonding process, a fusible metal alloy (e.g., solder) can be provided between the conductors of two elements, heated to melt the alloy, and cooled to form the connection between the two elements. The resulting bond often evinces sharp interfaces with conductors from both elements, and is subject to reversal by reheating. By way of contrast, direct metal bonding as employed in hybrid bonding does not require melting or an intermediate fusible metal alloy, and can result in strong mechanical and electrical connections, often demonstrating interdiffusion of the bonded conductive features with grain growth across the bonding interface between the elements, even without the much higher temperatures and pressures of thermocompression bonding.

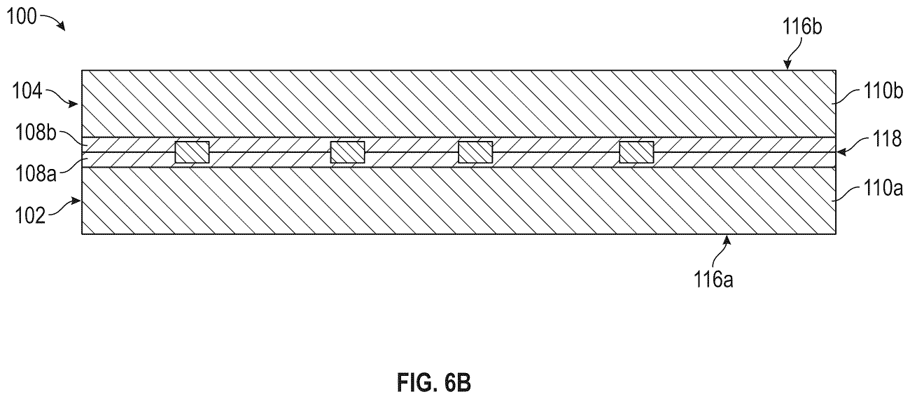

FIGS. 6A and 6B schematically illustrate cross-sectional side views of first and second elements 102, 104 prior to and after, respectively, a process for forming a directly bonded structure, and more particularly a hybrid bonded structure, according to some embodiments. In FIG. 6B, a bonded structure 100 comprises the first and second elements 102 and 104 that are directly bonded to one another at a bond interface 118 without an intervening adhesive. Conductive features 106a of a first element 102 may be electrically connected to corresponding conductive features 106b of a second element 104. In the illustrated hybrid bonded structure 100, the conductive features 106a are directly bonded to the corresponding conductive features 106b without intervening solder or conductive adhesive.

The conductive features 106a and 106b of the illustrated embodiment are embedded in, and can be considered part of, a first bonding layer 108a of the first element 102 and a second bonding layer 108b of the second element 104, respectively. Field regions of the bonding layers 108a, 108b extend between and partially or fully surround the conductive features 106a, 106b. The bonding layers 108a, 108b can comprise layers of non-conductive materials suitable for direct bonding, as described above, and the field regions are directly bonded to one another without an adhesive. The non-conductive bonding layers 108a, 108b can be disposed on respective front sides 114a, 114b of base substrate portions 110a, 110b.

The first and second elements 102, 104 can comprise microelectronic elements, such as semiconductor elements, including, for example, integrated device dies, wafers, passive devices, discrete active devices such as power switches, MEMS, etc. In some embodiments, the base substrate portion can comprise a device portion, such as a bulk semiconductor (e.g., silicon) portion of the elements 102, 104, and back-end-of-line (BEOL) interconnect layers over such semiconductor portions. The bonding layers 108a, 108b can be provided as part of such BEOL layers during device fabrication, as part of redistribution layers (RDL), or as specific bonding layers added to existing devices, with bond pads extending from underlying contacts. Active devices and/or circuitry (not shown) can be patterned and/or otherwise disposed in or on the base substrate portions 110a, 110b, and can electrically communicate with at least some of the conductive features 106a, 106b. Active devices and/or circuitry can be disposed at or near the front sides 114a, 114b of the base substrate portions 110a, 110b, and/or at or near opposite backsides 116a, 116b of the base substrate portions 110a, 110b. In other embodiments, one or both of the elements 102, 104 may not include active circuitry, but may instead comprise dummy elements, passive interposers, passive optical elements (e.g., glass substrates, gratings, lenses), etc. The bonding layers 108a, 108b are shown as being provided on the front sides of the elements, but similar bonding layers can be additionally or alternatively provided on the back sides of the elements.

In some embodiments, the base substrate portions 110a, 110b can have significantly different coefficients of thermal expansion (CTEs), and bonding elements that include such different based substrate portions can form a heterogenous bonded structure. The CTE difference between the base substrate portions 110a and 110b, and particularly between bulk semiconductor (typically single crystal) portions of the base substrate portions 110a, 110b, can be greater than 5 ppm/° C. or greater than 10 ppm/° C. For example, the CTE difference between the base substrate portions 110a and 110b can be in a range of 5 ppm/° C. to 100 ppm/° C., 5 ppm/° C. to 40 ppm/° C., 10 ppm/° C. to 100 ppm/° C., or 10 ppm/° C. to 40 ppm/° C.

In some embodiments, one of the base substrate portions 110a, 110b can comprise optoelectronic single crystal materials, including perovskite materials, that are useful for optical piezoelectric or pyroelectric applications, and the other of the base substrate portions 110a, 110b comprises a more conventional substrate material. For example, one of the base substrate portions 110a, 110b comprises lithium tantalate (LiTaO3) or lithium niobate (LiNbO3), and the other one of the base substrate portions 110a, 110b comprises silicon (Si), quartz, fused silica glass, sapphire, or a glass. In other embodiments, one of the base substrate portions 110a, 110b comprises a III-V single semiconductor material, such as gallium arsenide (GaAs) or gallium nitride (GaN), and the other one of the base substrate portions 110a, 110b can comprise a non-III-V semiconductor material, such as silicon (Si), or can comprise other materials with similar CTE, such as quartz, fused silica glass, sapphire, or a glass. In still other embodiments, one of the base substrate portions 110a, 110b comprises a semiconductor material and the other of the base substrate portions 110a, 110b comprises other materials, such as a glass, organic or ceramic substrate.

In some arrangements, the first element 102 can comprise a singulated element, such as a singulated integrated device die. In other arrangements, the first element 102 can comprise a carrier or substrate (e.g., a semiconductor wafer) that includes a plurality (e.g., tens, hundreds, or more) of device regions that, when singulated, forms a plurality of integrated device dies, though in other embodiments such a carrier can be a package substrate (e.g., a laminate substrate, a ceramic substrate, etc.) or a passive or active interposer. Similarly, the second element 104 can comprise a singulated element, such as a singulated integrated device die. In other arrangements, the second element 104 can comprise a carrier or substrate (e.g., a semiconductor wafer). The embodiments disclosed herein can accordingly apply to wafer-to-wafer (W2W), die-to-die (D2D), or die-to-wafer (D2W) bonding processes. In W2W processes, two or more wafers can be directly bonded to one another (e.g., direct hybrid bonded) and singulated using a suitable singulation process. After singulation, side edges of the singulated structure (e.g., the side edges of the two bonded elements) can be substantially flush (substantially aligned x-y dimensions) and/or the edges of the bonding layers for both bonded and singulated elements can be coextensive, and may include markings indicative of the common singulation process for the bonded structure (e.g., saw markings if a saw singulation process is used).

While only two elements 102, 104 are shown, any suitable number of elements can be stacked in the bonded structure 100. For example, a third element (not shown) can be stacked on the second element 104, a fourth element (not shown) can be stacked on the third element, and so forth. In such implementations, through substrate vias (TSVs) can be formed to provide vertical electrical communication between and/or among the vertically-stacked elements. Additionally or alternatively, one or more additional elements (not shown) can be stacked laterally adjacent one another along the first element 102. In some embodiments, a laterally stacked additional element may be smaller than the second element. In some embodiments, the bonded structure can be encapsulated with an insulating material, such as an inorganic dielectric (e.g., silicon oxide, silicon nitride, silicon oxynitrocarbide, etc.). One or more insulating layers can be provided over the bonded structure. For example, in some implementations, a first insulating layer can be conformally deposited over the bonded structure, and a second insulating layer (which may include be the same material as the first insulating layer, or a different material) can be provided over the first insulating layer.

To effectuate direct bonding between the bonding layers 108a, 108b, the bonding layers 108a, 108b can be prepared for direct bonding. Non-conductive bonding surfaces 112a, 112b at the upper or exterior surfaces of the bonding layers 108a, 108b can be prepared for direct bonding by polishing, for example, by chemical mechanical polishing (CMP). The roughness of the polished bonding surfaces 112a, 112b can be less than 30 Å rms. For example, the roughness of the bonding surfaces 112a and 112b can be in a range of about 0.1 Å rms to 15 Å rms, 0.5 Å rms to 10 Å rms, or 1 Å rms to 5 Å rms. Polishing can also be tuned to leave the conductive features 106a, 106b recessed relative to the field regions of the bonding surfaces 112a, 112b.

Preparation for direct bonding can also include cleaning and exposing one or both of the bonding surfaces 112a, 112b to a plasma and/or etchants to activate at least one of the surfaces 112a, 112b. In some embodiments, one or both of the surfaces 112a, 112b can be terminated with a species after activation or during activation (e.g., during the plasma and/or etch processes). Without being limited by theory, in some embodiments, the activation process can be performed to break chemical bonds at the bonding surface(s) 112a, 112b, and the termination process can provide additional chemical species at the bonding surface(s) 112a, 112b that alters the chemical bond and/or improves the bonding energy during direct bonding. In some embodiments, the activation and termination are provided in the same step, e.g., a plasma to activate and terminate the surface(s) 112a, 112b. In other embodiments, one or both of the bonding surfaces 112a, 112b can be terminated in a separate treatment to provide the additional species for direct bonding. In various embodiments, the terminating species can comprise nitrogen. For example, in some embodiments, the bonding surface(s) 112a, 112b can be exposed to a nitrogen-containing plasma. Other terminating species can be suitable for improving bonding energy, depending upon the materials of the bonding surfaces 112a, 112b. Further, in some embodiments, the bonding surface(s) 112a, 112b can be exposed to fluorine. For example, there may be one or multiple fluorine concentration peaks at or near a bond interface 118 between the first and second elements 102, 104. Typically, fluorine concentration peaks occur at interfaces between material layers. Additional examples of activation and/or termination treatments may be found in U.S. Pat. No. 9,391,143 at Col. 5, line 55 to Col. 7, line 3; Col. 8, line 52 to Col. 9, line 45; Col. 10, lines 24-36; Col. 11, lines 24-32, 42-47, 52-55, and 60-64; Col. 12, lines 3-14, 31-33, and 55-67; Col. 14, lines 38-40 and 44-50; and U.S. Pat. No. 10,434,749 at Col. 4, lines 41-50; Col. 5, lines 7-22, 39, 55-61; Col. 8, lines 25-31, 35-40, and 49-56; and Col. 12, lines 46-61, the activation and termination teachings of which are incorporated by reference herein.

Thus, in the directly bonded structure 100, the bond interface 118 between two non-conductive materials (e.g., the bonding layers 108a, 108b) can comprise a very smooth interface with higher nitrogen (or other terminating species) content and/or fluorine concentration peaks at the bond interface 118. In some embodiments, the nitrogen and/or fluorine concentration peaks may be detected using various types of inspection techniques, such as SIMS techniques. The polished bonding surfaces 112a and 112b can be slightly rougher (e.g., about 1 Å rms to 30 Å rms, 3 Å rms to 20 Å rms, or possibly rougher) after an activation process. In some embodiments, activation and/or termination can result in slightly smoother surfaces prior to bonding, such as where a plasma treatment preferentially smooths out high points on the bonding surface.

The non-conductive bonding layers 108a and 108b can be directly bonded to one another without an adhesive. In some embodiments, the elements 102, 104 are brought together at room temperature, without the need for application of a voltage, and without the need for application of external pressure or force beyond that used to initiate contact between the two elements 102, 104. Contact alone can cause direct bonding between the non-conductive surfaces of the bonding layers 108a, 108b (e.g., covalent dielectric bonding). Subsequent annealing of the bonded structure 100 can cause the conductive features 106a, 106b to directly bond.

In some embodiments, prior to direct bonding, the conductive features 106a, 106b are recessed relative to the surrounding bonding surfaces, such that a total gap between opposing contacts after dielectric bonding and prior to anneal is less than 15 nm, or less than 10 nm. Because the recess depths for the conductive features 106a and 106b can vary across each element, due to process variation, the noted gap can represent a maximum or an average gap between corresponding conductive features 106a, 106b of two joined elements (prior to anneal). Upon annealing, the conductive features 106a and 106b can expand and contact one another to form a metal-to-metal direct bond.

During annealing, the conductive features 106a, 106b (e.g., metallic material) can expand while the direct bonds between surrounding non-conductive materials of the bonding layers 108a, 108b resist separation of the elements, such that the thermal expansion increases the internal contact pressure between the opposing conductive features. Annealing can also cause metallic grain growth across the bonding interface, such that grains from one element migrate across the bonding interface at least partially into the other element, and vice versa. Thus, in some hybrid bonding embodiments, opposing conductive materials are joined without heating above the conductive materials' melting temperature. In various embodiments, bonds can form at lower temperatures compared to soldering or thermocompression bonding.

In various embodiments, the conductive features 106a, 106b can comprise discrete pads, contacts, electrodes, or traces at least partially embedded in the non-conductive field regions of the bonding layers 108a, 108b. In some embodiments, the conductive features 106a, 106b can comprise exposed contact surfaces of TSVs (e.g., through silicon vias).

As noted above, in some embodiments, in the elements 102, 104 of FIG. 6A prior to direct bonding, portions of the respective conductive features 106a and 106b can be recessed below the non-conductive bonding surfaces 112a and 112b, for example, recessed by less than 30 nm, less than 20 nm, less than 15 nm, or less than 10 nm, for example, recessed in a range of 2 nm to 20 nm, or in a range of 4 nm to 10 nm. Due to process variation, both dielectric thickness and conductor recess depths can vary across an element. Accordingly, the above recess depth ranges may apply to individual conductive features 106a, 106b or to average depths of the recesses relative to local non-conductive field regions. Even for an individual conductive feature 106a, 106b, the vertical recess can vary across the surface of the feature, and can be measured at or near the lateral middle or center of the cavity in which a given conductive feature 106a, 106b is formed, or can be measured at the sides of the cavity.

Beneficially, the use of hybrid bonding techniques (such as Direct Bond Interconnect, or DBI®, techniques commercially available from Adeia of San Jose, CA) can enable high density of connections between conductive features 106a, 106b across the direct bond interface 118 (e.g., small or fine pitches for regular arrays).

In some embodiments, a pitch p of the conductive features 106a, 106b, such as conductive traces embedded in the bonding surface of one of the bonded elements, may be less than 40 μm, less than 20 μm, less than 10 μm, less than 5 μm, less than 2 μm, or even less than 1 μm. For some applications, the ratio of the pitch of the conductive features 106a and 106b to one of the lateral dimensions (e.g., a diameter) of the bonding pad is less than is less than 20, or less than 10, or less than 5, or less than 3 and sometimes desirably less than 2. In various embodiments, the conductive features 106a and 106b and/or traces can comprise copper or copper alloys, although other metals may be suitable, such as nickel, aluminum, or alloys thereof. The conductive features disclosed herein, such as the conductive features 106a and 106b, can comprise fine-grain metal (e.g., a fine-grain copper). Further, a major lateral dimension (e.g., a pad diameter) can be small as well, e.g., in a range of about 0.25 μm to 30 μm, in a range of about 0.25 μm to 5 μm, or in a range of about 0.5 μm to 5 μm. For hybrid bonded elements 102, 104, as shown, the orientations of one or more conductive features 106a, 106b from opposite elements can be opposite to one another. As is known in the art, conductive features in general can be formed with close to vertical sidewalls, particularly where directional reactive ion etching (RIE) defines the conductor sidewalls either directly though etching the conductive material or indirectly through etching surrounding insulators in damascene processes. However, some slight taper to the conductor sidewalls can be present, wherein the conductor becomes narrower farther away from the surface initially exposed to the etch. The taper can be even more pronounced when the conductive sidewall is defined directly or indirectly with isotropic wet or dry etching. In the illustrated embodiment, at least one conductive feature 106b in the bonding layer 108b (and/or at least one internal conductive feature, such as a BEOL feature) of the upper element 104 may be tapered or narrowed upwardly, away from the bonding surface 112b. By way of contrast, at least one conductive feature 106a in the bonding layer 108a (and/or at least one internal conductive feature, such as a BEOL feature) of the lower element 102 may be tapered or narrowed downwardly, away from the bonding surface 112a. Similarly, any bonding layers (not shown) on the backsides 116a, 116b of the elements 102, 104 may taper or narrow away from the backsides, with an opposite taper orientation relative to front side conductive features 106a, 106b of the same element.

As described above, in an anneal phase of hybrid bonding, the conductive features 106a, 106b can expand and contact one another to form a metal-to-metal direct bond. In some embodiments, the materials of the conductive features 106a, 106b of opposite elements 102, 104 can interdiffuse during the annealing process. In some embodiments, metal grains grow into each other across the bond interface 118. In some embodiments, the metal is or includes copper, which can have grains oriented along the 111 crystal plane for improved copper diffusion across the bond interface 118. In some embodiments, the conductive features 106a and 106b may include nanotwinned copper grain structure, which can aid in merging the conductive features during anneal. There is substantially no gap between the non-conductive bonding layers 108a and 108b at or near the bonded conductive features 106a and 106b. In some embodiments, a barrier layer may be provided under and/or laterally surrounding the conductive features 106a and 106b (e.g., which may include copper). In other embodiments, however, there may be no barrier layer under the conductive features 106a and 106b.

### Additional Embodiments

In the foregoing specification, the systems and processes have been described with reference to specific embodiments thereof. It will, however, be evident that various modifications and changes may be made thereto without departing from the broader spirit and scope of the embodiments disclosed herein. The specification and drawings are, accordingly, to be regarded in an illustrative rather than restrictive sense.

Indeed, although the systems and processes have been disclosed in the context of certain embodiments and examples, it will be understood by those skilled in the art that the various embodiments of the systems and processes extend beyond the specifically disclosed embodiments to other alternative embodiments and/or uses of the systems and processes and obvious modifications and equivalents thereof. In addition, while several variations of the embodiments of the systems and processes have been shown and described in detail, other modifications, which are within the scope of this disclosure, will be readily apparent to those of skill in the art based upon this disclosure. It is also contemplated that various combinations or sub-combinations of the specific features and embodiments of the embodiments may be made and still fall within the scope of the disclosure. It should be understood that various features and embodiments of the disclosed embodiments can be combined with, or substituted for, one another in order to form varying modes of the embodiments of the disclosed systems and processes. Any methods disclosed herein need not be performed in the order recited. Thus, it is intended that the scope of the systems and processes herein disclosed should not be limited by the particular embodiments described above.

It will be appreciated that the systems and methods of the disclosure each have several innovative embodiments, no single one of which is solely responsible or required for the desirable attributes disclosed herein. The various features and processes described above may be used independently of one another or may be combined in various ways. All possible combinations and sub-combinations are intended to fall within the scope of this disclosure.

Certain features that are described in this specification in the context of separate embodiments also may be implemented in combination in a single embodiment. Conversely, various features that are described in the context of a single embodiment also may be implemented in multiple embodiments separately or in any suitable sub-combination. Moreover, although features may be described above as acting in certain combinations and even initially claimed as such, one or more features from a claimed combination may in some cases be excised from the combination, and the claimed combination may be directed to a sub-combination or variation of a sub-combination. No single feature or group of features is necessary or indispensable to each and every embodiment.

It will also be appreciated that conditional language used herein, such as, among others, “can,” “could,” “might,” “may,” “for example,” and the like, unless specifically stated otherwise, or otherwise understood within the context as used, is generally intended to convey that certain embodiments include, while other embodiments do not include, certain features, elements and/or steps. Thus, such conditional language is not generally intended to imply that features, elements and/or steps are in any way required for one or more embodiments or that one or more embodiments necessarily include logic for deciding, with or without author input or prompting, whether these features, elements and/or steps are included or are to be performed in any particular embodiment. The terms “comprising,” “including,” “having,” and the like are synonymous and are used inclusively, in an open-ended fashion, and do not exclude additional elements, features, acts, operations, and so forth. In addition, the term “or” is used in its inclusive sense (and not in its exclusive sense) so that when used, for example, to connect a list of elements, the term “or” means one, some, or all of the elements in the list. In addition, the articles “a,” “an,” and “the” as used in this application and the appended claims are to be construed to mean “one or more” or “at least one” unless specified otherwise. Similarly, while operations may be depicted in the drawings in a particular order, it is to be recognized that such operations need not be performed in the particular order shown or in sequential order, or that all illustrated operations be performed, to achieve desirable results. Further, the drawings may schematically depict one or more example processes in the form of a flowchart. However, other operations that are not depicted may be incorporated in the example methods and processes that are schematically illustrated. For example, one or more additional operations may be performed before, after, simultaneously, or between any of the illustrated operations. Additionally, the operations may be rearranged or reordered in other embodiments. Additionally, other embodiments are within the scope of the following claims. In some cases, the actions recited in the claims may be performed in a different order and still achieve desirable results.

Further, while the methods and devices described herein may be susceptible to various modifications and alternative forms, specific examples thereof have been shown in the drawings and are herein described in detail. It should be understood, however, that the embodiments are not to be limited to the particular forms or methods disclosed, but, to the contrary, the embodiments are to cover all modifications, equivalents, and alternatives falling within the spirit and scope of the various implementations described and the appended claims. Further, the disclosure herein of any particular feature, aspect, method, property, characteristic, quality, attribute, element, or the like in connection with an implementation or embodiment can be used in all other implementations or embodiments set forth herein. Any methods disclosed herein need not be performed in the order recited. The methods disclosed herein may include certain actions taken by a practitioner; however, the methods can also include any third-party instruction of those actions, either expressly or by implication. The ranges disclosed herein also encompass any and all overlap, sub-ranges, and combinations thereof. Language such as “up to,” “at least,” “greater than,” “less than,” “between,” and the like includes the number recited. Numbers preceded by a term such as “about” or “approximately” include the recited numbers and should be interpreted based on the circumstances (for example, as accurate as reasonably possible under the circumstances, for example ±5%, ±10%, ±15%, etc.). For example, “about 3.5 mm” includes “3.5 mm.” Phrases preceded by a term such as “substantially” include the recited phrase and should be interpreted based on the circumstances (for example, as much as reasonably possible under the circumstances). For example, “substantially constant” includes “constant.” Unless stated otherwise, all measurements are at standard conditions including temperature and pressure.

As used herein, a phrase referring to “at least one of” a list of items refers to any combination of those items, including single members. As an example, “at least one of: A, B, or C” is intended to cover: A; B; C; A and B; A and C; B and C; and A, B, and C. Conjunctive language such as the phrase “at least one of X, Y and Z,” unless specifically stated otherwise, is understood with the context as used in general to convey that an item, term, etc. may be at least one of X, Y or Z. Thus, such conjunctive language is not generally intended to imply that certain embodiments require at least one of X, at least one of Y, and at least one of Z to each be present. The headings provided herein, if any, are for convenience only and do not necessarily affect the scope or meaning of the devices and methods disclosed herein.

Accordingly, the claims are not intended to be limited to the embodiments shown herein but are to be accorded ta fair interpretation consistent with this disclosure, the principles and the novel features disclosed herein.

1. A structure comprising:
a first processor die;
a first memory unit laterally spaced from the first processor die;
a first connecting element disposed vertically below the first processor die and the first memory unit, the first connecting element electrically connecting the first processor die and the first memory unit; and
a second connecting element disposed vertically above the first processor die and the first memory unit, the second connecting element electrically connecting the first processor die and the first memory unit,
wherein the first processor die communicates with the first memory unit through at least one of the first connecting element and the second connecting element.

2. The structure of claim 1, wherein the second connecting element comprises a redistribution layer (RDL), and wherein the first processor die communicates with the first memory unit through at least the RDL.

3. The structure of claim 2, wherein the first processor die comprises a first through substrate via (TSV), and wherein the first processor die communicates with the first memory unit through the RDL and the first TSV.

4. The structure of claim 2, further comprising a second processor die laterally spaced from the first processor die such that (i) the first processor die is disposed laterally between the second processor die and the first memory unit and (ii) the RDL is disposed vertically above the second processor die, wherein the second processor die communicates with the first memory unit through at least the RDL.

5. The structure of claim 1, wherein the first processor die comprises a neural networking processing unit (NPU), a tensor processing unit (TPU), a system on a chip (SOC), a central processing unit (CPU), or a graphics processing unit (GPU).

6. The structure of claim 1, wherein the first memory unit comprises a first stack of memory dies and a first controller logic.

7. The structure of claim 6, wherein the first controller logic is disposed vertically above or below the first stack of memory dies to enable communication between the first stack of memory dies and the first processor die.

8. The structure of claim 1, wherein the first connecting element comprises a bridge.

9. (canceled)

10. (canceled)

11. (canceled)

12. (canceled)

13. (canceled)

14. (canceled)

15. (canceled)

16. (canceled)

17. (canceled)

18. (canceled)

19. (canceled)

20. (canceled)

21. (canceled)

22. (canceled)

23. (canceled)

24. A structure comprising:
a first processor die;
a second processor die laterally spaced from the first processor die, the first processor die and the second processor die (i) forming at least a portion of a monolithic processor and (ii) disposed around a center of the monolithic processor;
a first memory unit laterally spaced from the first processor die and disposed around a first side of the monolithic processor, the first memory unit electrically connected to the first processor die;
a second memory unit laterally spaced from the second processor die and disposed around a second side of the monolithic processor, the second memory unit electrically connected to the second processor die; and
a redistribution layer (RDL) disposed vertically above the first processor die, the second processor die, the first memory unit, and the second memory unit for at least electrically connecting the first processor die and the second memory unit, and electrically connecting the second processor die and the first memory unit.

25. The structure of claim 24, wherein the first processor die, the second processor die, the first memory unit, and the second memory unit are disposed vertically above an interposer that comprises a first bridge and a second bridge.

26. The structure of claim 25, wherein the first memory unit is electrically connected to the first processor die through the first bridge and the second memory unit is electrically connected to the second processor die through the second bridge.

27. The structure of claim 26, wherein the first processor die communicates with the first memory unit through the first bridge, and communicates with the second memory unit through at least the RDL.

28. The structure of claim 26, wherein the second processor die communicates with the second memory unit through the second bridge, and communicates with the first memory unit through at least the RDL.

29. The structure of claim 24, further comprising a first dummy device disposed vertically directly above the first processor die and a second dummy device disposed vertically directly above the second processor die, wherein the first dummy device and the second dummy device are disposed vertically below the RDL.

30. The structure of claim 29, wherein the first dummy device is hybrid bonded to the first processor die and the second dummy device is hybrid bonded to the second processor die.

31. (canceled)

32. (canceled)

33. (canceled)

34. (canceled)

35. (canceled)

36. (canceled)

37. (canceled)

38. (canceled)

39. (canceled)

40. (canceled)

41. (canceled)

42. (canceled)

43. (canceled)

44. (canceled)

45. A method for forming a structure, the method comprising:
bonding a first processor die to a substrate, the substrate comprising a connecting element and disposed vertically below the first processor die;
bonding a first memory unit to the substrate, the substrate disposed vertically below the first memory unit; and
forming a redistribution layer (RDL) vertically above at least the first processor die and the first memory unit,
wherein the RDL electrically connects at least the first processor die and the first memory unit, and wherein the connecting element electrically connects the first processor die and the first memory unit.

46. The method of claim 45, further comprising:
bonding a second processor die to the substrate, the second processor die laterally spaced from the first processor die and disposed vertically above the substrate,
wherein the RDL is formed vertically above the second processor die for electrically connecting the second processor die and the first memory unit.

47. The method of claim 46, further comprising:
bonding a dummy thermal structure to the first processor die and the second processor die, the dummy thermal structure disposed vertically above the first processor die and the second processor die.

48. The method of claim 45, further comprising:
bonding a second memory unit to the RDL, the second memory unit disposed vertically above the RDL,
wherein the RDL electrically connects the first processor die and the second memory unit.

49. The method of claim 45, further comprising:
bonding a dummy device to the first processor die, the dummy device disposed vertically above the first processor die,
wherein the RDL is formed vertically above the dummy device, and wherein a combined thickness of the first processor die and the dummy device equals a thickness of the first memory unit.

50. (canceled)

51. (canceled)

52. (canceled)

53. (canceled)

54. (canceled)
